(19) United States
(12) Patent Application Publication
(10) Pub. No.: US 2025/0283930 A1
(43) Pub. Date: Sep. 11, 2025

(54) ELECTRICAL GRID FAULT LOCALIZATION

(71) Applicant: THE UNIVERSITY OF WESTERN ONTARIO, London, Ontario (CA)

(72) Inventors: Jacob HUNTE, London, Ontario (CA); Hanan LUTFIYYA, London, Ontario (CA); Anwar HAQUE, London, Ontario (CA); Michael DESROCHES, Brantford, Ontario (CA)

(21) Appl. No.: 18/569,161

(22) PCT Filed: Jun. 10, 2022
(86) PCT No.: PCT/CA2022/000027

§ 371 Date: Dec. 11, 2023

Related U.S. Application Data
(60) Provisional application No. 63/209,793, filed on Jun. 11, 2021.

(51) Int. Cl. G01R 31/08; G01R 19/25; H02J 13/00

(52) U.S. Cl. CPC G01R 31/086; G01R 19/2513; G01R 31/088; H02J 13/00002

(57) ABSTRACT

An electrical grid fault localization system including: a plurality of current sensors (measurement devices) electrically connected to the electrical grid; a memory for storing a representation of the electrical grid as a plurality of geographical markers, and for storing a plurality of sets of expected time data, each one of the plurality of sets of expected time data associated with each one of the plurality of geographical markers, each member of the set of expected time data based on an expected signal propagation time from, at least one of the plurality of geographical markers to at least one current sensor; a processor communicative with the plurality of current sensors and the memory, the processor configured to receive measured time data of a fault event from, the plurality of sensors to generate a set of fault event time data and to match the set of fault event time data to at least one of the plurality of sets of expected time data and identify in g/outputting at least one matched geographical marker. Methods and computer-readable media directed to electrical grid fault localization are also described.

### BACKGROUND OF THE INVENTION

### Field of the Invention

The present invention relates to power grids, and more particularly to fault localization in an electrical grid.

### Description of the Related Art

An electrical grid includes power plants, the transmission network and the distribution network. Power plants can generate power from one or more of a variety of sources including, for example, coal, water, oil, natural gas, or nuclear. Power plants are typically located miles away from power consumers. In order to transmit the power over large distances to consumers the power is sent over the transmission network through a transmission substation that converts the power to a high voltage suitable for long distance transmission. Once it reaches a cluster of electricity consumers it then uses the distribution network to deliver the power to the consumers. The transition from the transmission network to the distribution network is through a distribution substation which uses transformers to reduce the power voltage before it is transmitted to the consumers. As the power is transmitted through the distribution network it may go through multiple substations that further reduces the voltage before the power is received by consumers. A distribution feeder refers to the cables that transmit the power from substations.

Faults can occur at different stages throughout the electrical grid. These faults, given the amount of power passing through the grid, can cause massive damage to the equipment and even cause harm to people. Should a fault occur, the grid is designed to quickly stop sending power to that section of the grid. This protects people, the electrical grid, and its equipment.

To restore the power, the fault must first be localized. After this the fault can then be cleared and power can be restored. Faults can occur in both the transmission and distribution segments of the electrical grid. However due to the large area typically effected by a transmission grid level fault, initial localization techniques focused on the transmission grid. Most transmission grid fault localization techniques are based on impedance or travelling-waves.

For distribution grids, initial attempts focused on applying transmission grid solutions within the distribution grid. This had limited results since the distribution grid topology is more complex than the transmission grid. The characteristics of the distribution grid that makes it difficult to apply methods used in the transmission grid include the following: (i) The area covered by the distribution grid is smaller making small errors in localization much more complicated to correct; (ii) Distribution grids have many branches on any given feeder; (iii) The transmission grid largely focuses on one-way transfer of power from upstream (power generation plants) to downstream (cities); while in the distribution grid, there are frequent loops and switches that may cause the flow of power along a section of the network to be reversed or to take a different path entirely; (iv) A substantially higher number of components are present in distribution grids than in transmission grids, complicating calculations made for localization; (v) The structure of the distribution grid is more dynamic since new customers can be added much more often to the distribution grid; (vi) The information available for the distribution grid typically has more errors as its components are changed and new ones added; (vii) The distribution grid can have any number of different conductor types as several transformations are made on the voltage to step it down to consumer usage needs; (viii) Distribution networks have portions of their network placed underground which can change properties of variables used in some fault localization calculations.

To address the challenges in applying the general methods to the distribution grid, a number of solutions were developed. These solutions include the use of:
An enhanced analysis of travelling waves
Fuzzy set theory
Direct circuit analysis
Iterative fault distance
Impedance-based methods
Phasor measurement units
Smart meters
Current Sensors

This is by no means an exhaustive list of the methods developed but only seeks to capture a variety of these methods. The methods in this list represent a sample of some of the more common approaches taken to localize faults in distribution grids.

Use of multiple measurement devices like voltage and current sensors, smart meters and feeder meters is a promising approach for localizing faults in the distribution grid. In the context of electrical grids, a device consists of a sensor that reads electrical properties like current and voltage and network capabilities for transmitting the measurements. Both the term sensor and sensor device are used interchangeably as the related work uses both terms.

However, a challenge with the use of multiple devices is the synchronization of these devices. The fault data recorded by each device must be synchronized so that it can be used effectively. This is especially challenging because faults and the data they generate typically last fractions of seconds.

This requires an accurate clock as a few microseconds of error equates to hundreds of meters in distance calculations.

Clock synchronization have been achieved using a number of methods:
Berkeley algorithm—This technique uses the average time between multiple nodes as the correct time and all nodes are then adjusted to reflect this time.
Clock-sampling mutual network synchronization—This technique uses the fact that every clock in each node has a time drift factor. Once this factor is calculated by a node then their clocks can be corrected.
Cristian's algorithm—This method relies on the existence of an accurate time source and a time server. Clients then use the time server to retrieve the correct time.
Global Positioning System—GPS satellites have atomic clocks that allow them to be extremely accurate. The GPS satellite sends a signal which allows a receiving device to by synchronized to UTC.
Network Time Protocol—A very widely used method for achieving millisecond accuracy in unreliable networks and is used across the internet.
Precision Time Protocol—A master slave method of delivering highly accurate time that is used mainly for synchronization in local area networks.
Synchronous Ethernet—This technique transmits synchronization signals over the ethernet physical layer.

The quality and accuracy of fault localization methods are, therefore impacted by a third-party synchronization scheme and in many cases are dependent on an underlying computer communication network infrastructure. The reliance on third-party schemes and network infrastructure adds cost to implementation and maintenance and presents risk as to quality, accuracy and reliability.

Accordingly, there is a continuing need for alternative fault localization techniques.

### SUMMARY OF THE INVENTION

In an aspect there is provide an electrical grid fault localization system comprising:
a plurality of current sensors (measurement devices) electrically connected to the electrical grid;
a memory for storing a representation of the electrical grid as a plurality of geographical markers, and for storing a plurality of sets of expected time data, each one of the plurality of sets of expected time data associated with each one of the plurality of geographical markers, each member of the set of expected time data based on an expected signal propagation time from at least one of the plurality of geographical markers to at least one current sensor;
a processor communicative with the plurality of current sensors and the memory, the processor configured to receive measured time data of a fault event from the plurality of sensors to generate a set of fault event time data and to match the set of fault event time data to at least one of the plurality of sets of expected time data and identifying/outputting at least one matched geographical marker.

In another aspect there is provided, an electrical grid fault localization method comprising:
storing a representation of the electrical grid as a plurality of geographical markers;
storing a plurality of sets of expected time data, each one of the plurality of sets of expected time data associated with each one of the plurality of geographical markers, each member of the set of expected time data based on an expected signal propagation time from at least one of the plurality of geographical markers to at least one of a plurality of current sensors;
identifying a fault event wave signal with the plurality of current sensors (measurement devices) coupled to the electrical grid;
receiving measured time data of the fault event from the plurality of current sensors to generate a set of fault event time data; and
matching the set of fault event time data to at least one of the plurality of sets of expected time data and identifying/outputting at least one matched geographical marker.

In further aspects, further systems, methods and computer-readable media directed to electrical grid fault localization are provided.

### BRIEF DESCRIPTION OF THE DRAWINGS

FIG. 1 shows a block diagram of a system for electrical grid fault localization.

FIG. 2 shows a first variant of the system shown in FIG. 1.

FIG. 3 shows a second variant of the system shown in FIG. 1.

FIG. 4 shows a third variant of the system shown in FIG. 1.

FIG. 5 shows a fourth variant of the system shown in FIG. 1.

FIG. 6 shows a fifth variant of the system shown in FIG. 1.

FIG. 7 shows a sixth variant of the system shown in FIG. 1.

FIG. 8 shows a flow chart scheme of a method for electrical grid fault localization.

FIG. 9 shows a diagram of a current transformer as an example of a current sensor.

FIG. 10 shows an example of a change in current wave profile for fault and recloser events.

FIG. 11 shows an example of a magnified view of change in current wave profile for a fault event.

FIG. 12 shows an example of electrical grid node locations mapped in Google maps.

FIG. 13 shows a converted google maps feeder as a MATLAB graph object.

FIG. 14 shows a MATLAB graph feeder with optimized sensor locations (circled stars).

FIG. 15 shows a scheme for an edge key generation process.

FIG. 16 shows edge keys generated for all edges in a graph with 10 nodes.

FIG. 17 shows a scheme for an edge key search using a fault key.

FIG. 18 shows a test result demonstrating accurate fault location display on a graph object.

FIG. 19 shows a test result demonstrating accurate fault location display in Google maps interface.

FIG. 20 shows a test result demonstrating accurate fault area display on a graph object when using a sub-optimal number of sensors.

FIG. 21 shows a test result demonstrating accurate fault area display in Google maps interface when using a sub-optimal number of sensors.

FIG. 22 shows current data before, during and after a fault.

FIG. 23 shows a plot of a change in current of measured fault and reclosure signal data for one phase, and is the same as the plot shown in FIG. 10 with more complete axis labels.

FIG. 24 shows an example of a cable, sensors and recloser.

FIG. 25 shows a plot of error rate reduction from increase in sample rate.

FIG. 26 shows an example of a problem of multiple fault locations due to multiple paths that can be challenging to distinguish using impedance-based methods.

FIG. 27 shows an example of a problem of multiple fault locations due to unknown wave sources that can be challenging to distinguish using travelling wave methods.

FIG. 28 shows an example of a single power line to demonstrate calculation of a fault location.

FIG. 29 shows an example of a power line segmented for time-window calculation.

FIG. 30 shows an example of distribution grid with three sensors.

FIG. 31 shows a comparison of computational resource usage for greedy algorithm solutions versus genetic algorithm solutions.

FIG. 32 shows a comparison of PLE coverage for greedy algorithm solutions versus genetic algorithm solutions.

FIG. 33 shows amounts of improvement in PLE coverage for hybrid algorithm solutions over greedy algorithm solutions.

FIG. 34 shows a comparison of computational resource usage for greedy algorithm solutions versus genetic algorithm solutions versus hybrid algorithm solutions.

FIG. 35 shows a comparison of PLE coverage for placement of 2 to 50 sensors for hybrid algorithm solutions.

FIG. 36 shows amount of PLE coverage gained for each additional sensor from 2 to 50 sensors for hybrid algorithm solutions.

FIG. 37 shows an example grid using three sensor devices and one recloser.

FIG. 38 shows a schematic illustration of a measured delay between fault and recloser signals of each sensor of the grid example shown in FIG. 37.

FIG. 39 shows a schematic of alignment of the recloser signals (left) and then the fault signals (right) across multiple devices of the grid example shown in FIG. 37.

FIG. 40 shows a schematic of incident and reflected waves/signals in an electrical grid.

FIG. 41 shows a schematic and equation for a single-ended fault localization in the electrical grid shown in FIG. 40.

FIG. 42 shows a schematic and equation for a multiple-ended fault localization due to unknown wave sources in the electrical grid shown in FIG. 27.

### DETAILED DESCRIPTION OF PREFERRED EMBODIMENTS

Referring to the drawings, an electrical grid fault localization system and method is now described.

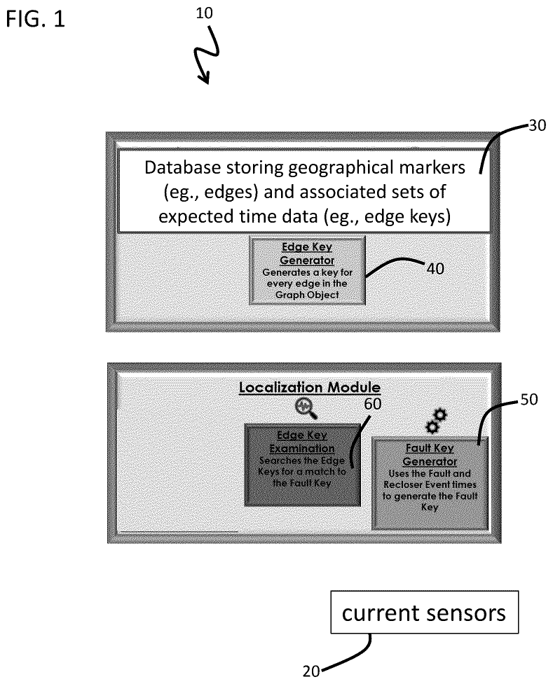

FIG. 1 shows a block diagram schematic view of an electrical grid fault localization system 10. The an electrical grid fault localization system 10 employs measuring devices for determining signal propagation times and executes a comparison of a measured signal propagation time during a fault event to a database of expected signal propagation times from a plurality of geographic markers to each measuring device to identify at least one geographical marker location at or near the fault event. The system 10 comprises a plurality of current sensors 20 electrically connected to the electrical grid at a variety of locations, each current sensor configured to measure electrical signals that are communicated through each current sensor location in the electrical grid.

The system 10 includes a database 30 storing a representation of the electrical grid as a plurality of geographical markers, and for storing a plurality of sets of expected time data 40, each one of the plurality of sets of expected time data associated with each one of the plurality of geographical markers, each member of the set of expected time data based on an expected signal propagation time from at least one of the plurality of geographical markers to at least one current sensor, the plurality of sets of expected time data generated by a first key generator 40.

The system 10 further includes a second key generator 50 configured to receive measured time data of a fault event from the plurality of sensors to generate a set of fault event time data and a key examiner 60 to match the set of fault event time data to at least one of the plurality of sets of expected time data and identifying/outputting at least one matched geographical marker.

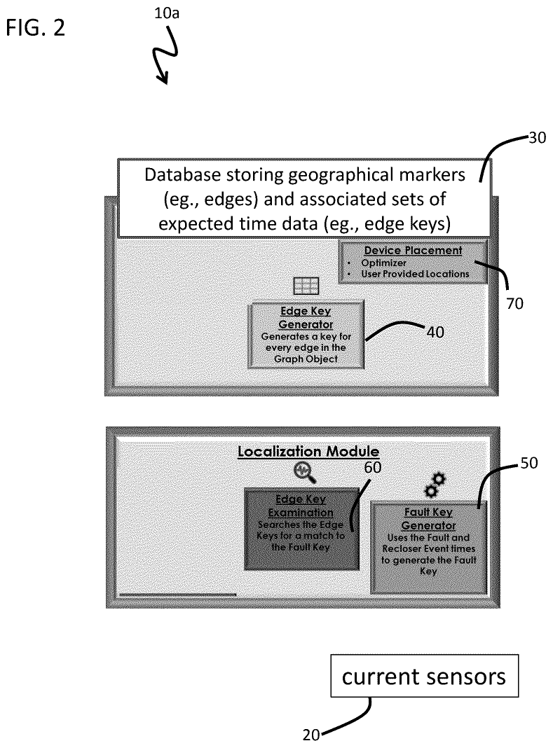

FIG. 2 shows a block diagram schematic view of a first variant system 10a. The first variant system 10a includes the components of system 10, and further includes a current-sensor-placement component 70 for determining placement of the plurality of current sensors. The current-sensor-placement component 70 determines placement of the plurality of current sensors based on maximizing occurrence of unique sets within the plurality of sets of expected time data.

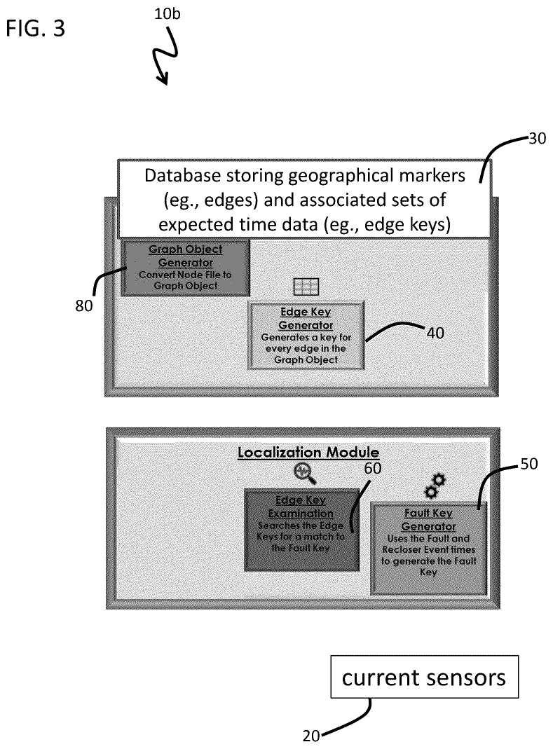

FIG. 3 shows a block diagram schematic view of a second variant system 10b. The second variant system 10b includes the components of system 10, and further includes a graph-object-generator component 80 to represent the electrical grid as a graph object based on the plurality of geographical markers. The graph object is generated based on a geographical map and a geographical coordinate for each of the plurality of geographical markers. An example of a geographical coordinate is a Global Positioning System coordinate.

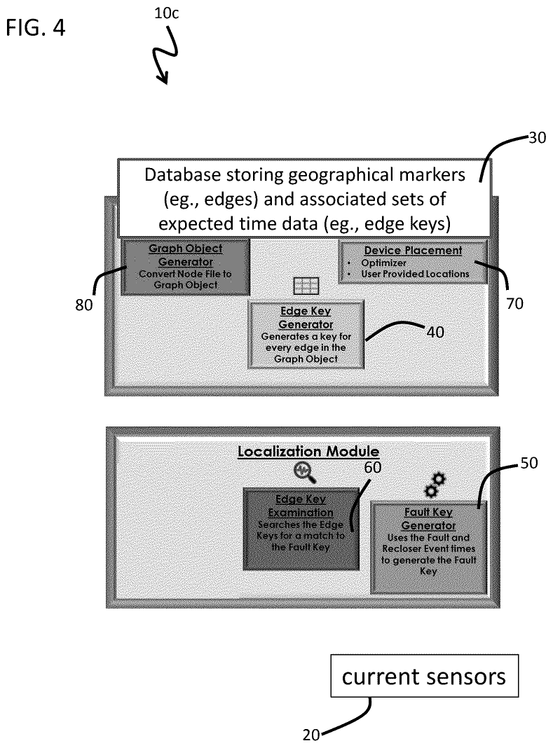

FIG. 4 shows a block diagram schematic view of a third variant system 10c. The third variant system 10c includes the components of system 10, and further includes the current-sensor-placement component 70 for determining placement of the plurality of current sensors and also further includes the graph-object-generator component 80 to represent the electrical grid as a graph object based on the plurality of geographical markers. The current-sensor-placement component 70 uses the graph object or graph data provided by the graph-object-generator 80 to determining placement locations for the plurality of current sensors 70. The graph-object-generator 80 uses current sensor placement location data provided by the current-sensor-placement component 70 to incorporate current sensor locations in the graph object.

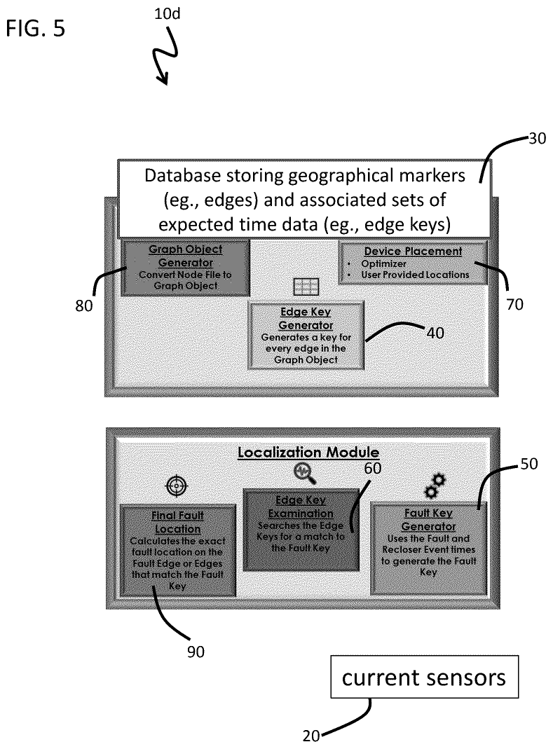

FIG. 5 shows a block diagram schematic view of a fourth variant system 10d. The fourth variant system 10d includes the components of the third variant system 10c, and further includes a higher spatial specificity/resolution fault localizer 90 as compared to lower spatial specificity/resolution fault localization provided by the key examiner 60 and associated matching algorithms. The fault localizer 90 makes use of the at least one matched geographical marker determined by the key examiner 60 to provide a fault localization relative to the at least one matched geographical marker calculated based on selecting a pair of current sensors from the plurality of current sensors and determining a distance interval of the fault location relative to the at least one matched geographical marker. More specifically, the fault localizer 90 determines a time interval between a differential of an expected signal propagation time from the at least one matched geographical marker to the selected pair of current sensors and a differential of a fault event wave signal propagation time from the fault location to the selected pair of current sensors; and converting the time interval to a distance interval related to the at least one matched geographical marker.

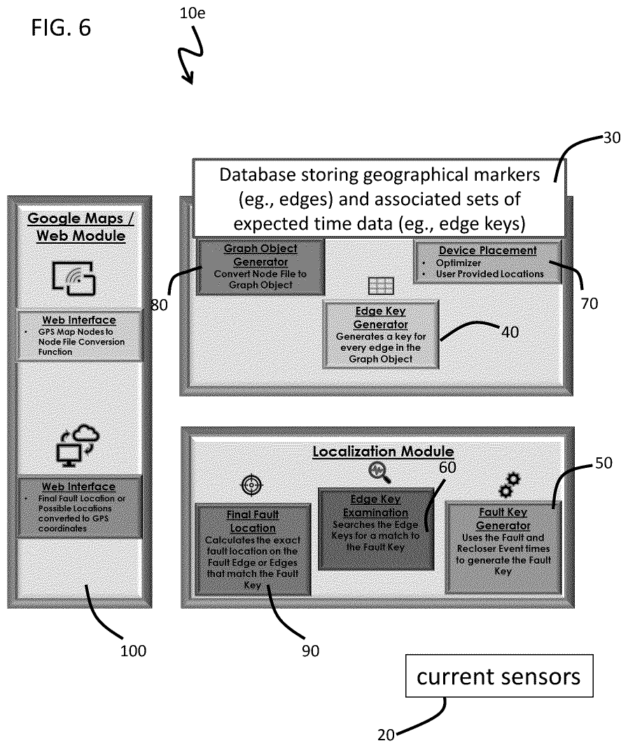

FIG. 6 shows a block diagram schematic view of a fifth variant system 10e. The fifth variant system 10e includes the components of the fourth variant system 10d, and further includes a web-interface component 100 for communicating a map displaying the plurality of geographical markers and for communicating a map displaying the at least one matched geographical marker provided by the key examiner 60. The web-interface component 100 can also communicate a map displaying the fault localization relative to the at least one matched geographical marker and may alternatively display the fault localization without displaying the related at least one matched geographical marker.

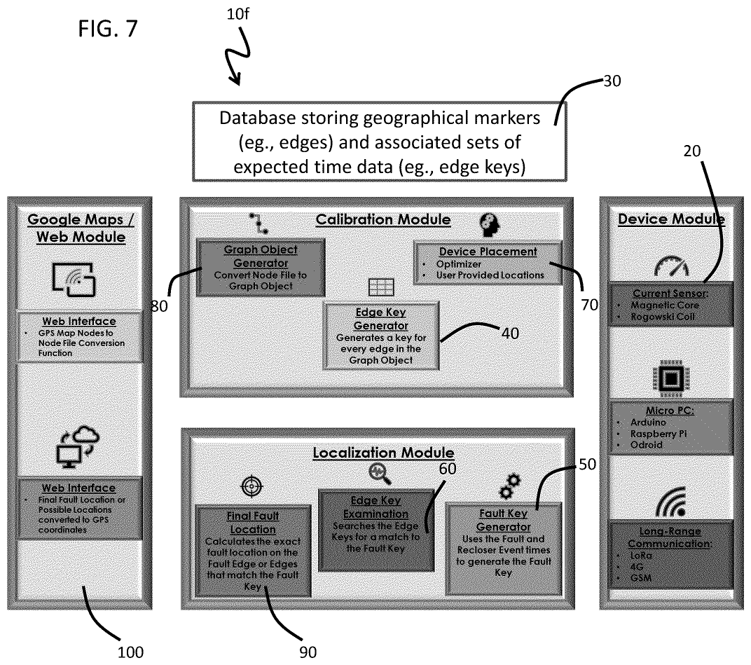

FIG. 7 shows a block diagram schematic view of a sixth variant system 10f. The sixth variant system 10f includes the components of the fifth variant system 10e, and further includes each current sensor incorporated within a device that includes a microcomputer and a wireless communicator.

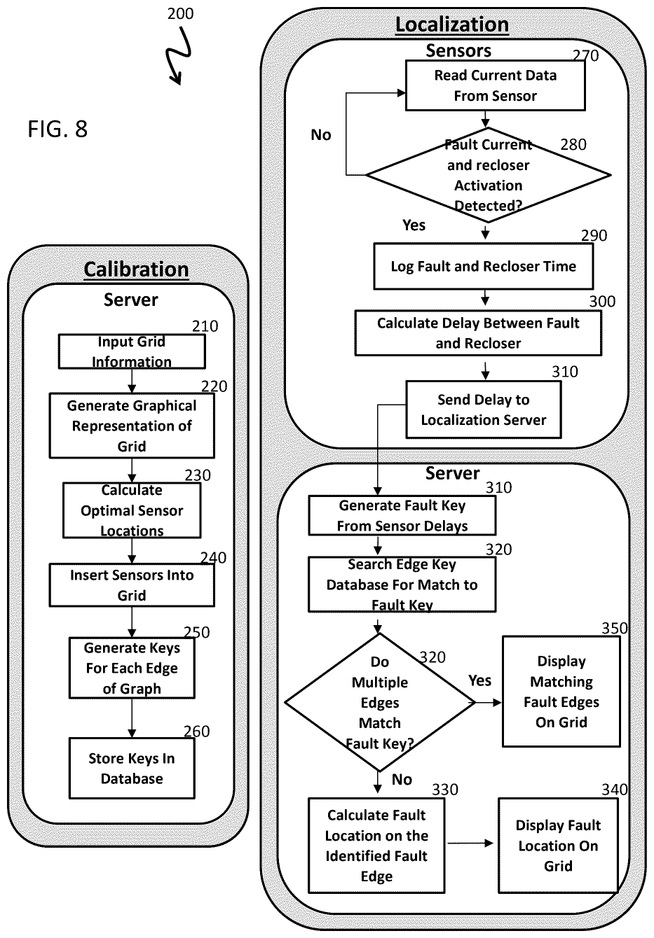

FIG. 8 shows a flow chart scheme of a method 200 of using the sixth variant system 10f, and may readily be adapted to any of system 10 and any of its variants by reconciling method steps with components shown for each respective system variant.

Method 200 includes a calibration stage and a localization stage. The calibration stage is focused on collecting information about the grid being monitored. It also optimizes sensor placement to maximize the efficiency of all sensors used. It then uses the data on the grid and the location of the sensors to create key data structures used to localize the fault during the localization stage. It is possible to update the grid with new line data or sensor locations. Updating the information on lines and other grid components can be accommodated by a system re-calibration. The following steps cover the calibration process:

1. User Inputs the GPS coordinates for the reclosers and lines in the electrical grid being monitored (step 210).

2. GPS locations are converted to a graph with weighted edges representing distances (step 220).

3. Run optimization algorithm on graph for sensor placement or load locations provided by user (step 230) and add sensor locations to graph object (step 240).

4. Create a key for every edge in the graph (each generated key may be referred to as an edge key) (step 250) and store all generated keys in memory (step 260).

The localization stage monitors and handles occurrence of faults. When a fault occurs data (fault and recloser incident wave time stamps) from the sensors placed in the electrical grid is received and converted into a key (referred to as a fault key) which is then used to determine the fault location.

5. When a fault occurs, the current sensors detect the fault and recloser events by measuring abnormal current in the grid (step 270). Once abnormal current is detected it is recorded and sent to a microcomputer.

6. The microcomputer on each sensor device analyses the current data and identifies the incident waves generated by the fault and recloser (step 280). The times that these incident waves are detected at each sensor are then recorded (step 290) and the delay between these incident waves is calculated (step 300).

7. The detection times recorded at each sensor device must then be transmitted with the sensor device's unique identifier to the localization module (step 310). The data is sent wirelessly and depending on the environment, the method used to transfer this data may differ.

8. The fault and recloser incident wave times are used to generate the fault key (step 310). The recloser wave time is used to account for the inaccuracies of each sensor device clock that may be caused by clock drift.

9. The edge keys are then searched using the fault key to find a match by comparing the fault key to the edge keys generated during calibration (step 320).

10. The edge key that matches the fault key is selected as the fault location edge and a calculation is performed using the fault key and its matched edge key to provide a fault location within the fault edge (step 330).

11. The fault location is then converted into a GPS coordinate and displayed on a map showing the user the fault location (step 340).

12. If the fault key matches multiple edge keys then the corresponding multiple edge locations are displayed on the map (step 350).

The electrical grid fault localization system and method have been validated by experimental testing. Experimental testing results demonstrate the ability of the electrical grid fault localization system and method to determine fault locations based on comparing measured fault event wave time data with sets of expected signal propagation time data associated with a plurality of geographical markers. The following experimental examples are for illustration purposes only and are not intended to be a limiting description.

### Experimental Example 1

This experimental example demonstrates construction and testing of the sixth variant system 10f as shown in FIG. 7, and methods of operation as shown in FIG. 8.

The sixth variant system 10f includes four modules. These modules cover interactions with the user and the electrical grid and include the following:
Web/Maps Module—Retrieve data on the grid from the user and display localization results;
Sensor Device Module—Passively monitor the electrical grid being and detect fault and recloser events;
Calibration Module—create a graph model of the electrical grid, recommend optimal locations for monitoring sensor devices and generate data structures for localization;
Localization Module—process fault and recloser data packets received from sensors and localize the fault.

Each of these modules are made up of components or processes that provide the overall functionality of their module, which are now described in greater detail.

### Experimental Example 1.1: Sensor Device Module

This module requires a hardware component. The hardware component is the set of sensor devices placed in the grid that passively monitor the distribution grid. A sensor device consists of the following components:
A sensor that monitors the current (referred to in the industry as a current sensor);
A microcomputer (also referred to as microprocessor or micro-PC) that analyzes the measured current data to determine when a fault has occurred;
A long-range communication system that transmits the times to the localization module.

The sensor devices are placed in the distribution grid. The rest of this section describes the sensor device components.

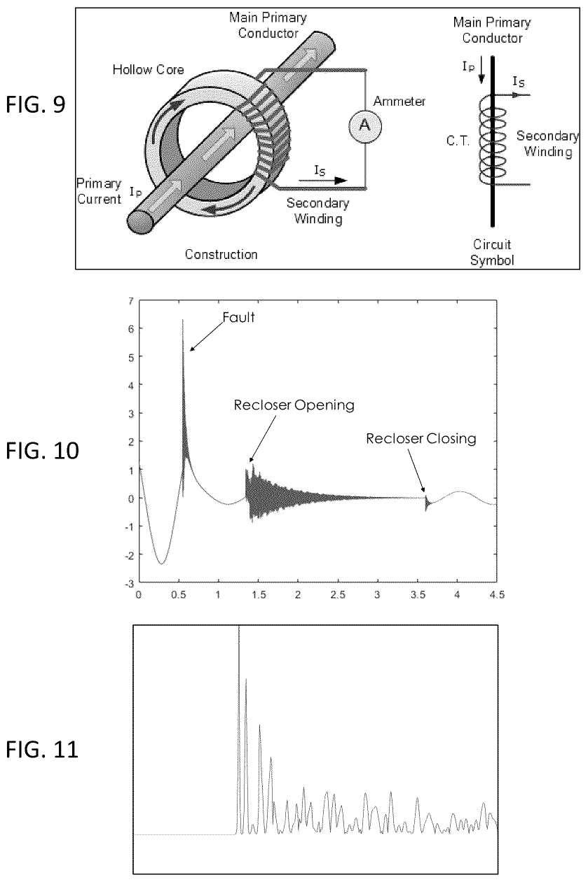

A current sensor detects and converts current in a wire and generates a signal proportional to that current. In illustrative examples, as shown in FIG. 9, the current sensor can be either a current transformer or a Rogowski Coil. The purpose of these sensors is to reduce the measured high current to a current or voltage that can then be recorded. The sensor should be able to detect the incident waves for the fault and the recloser events.

The current being measured changes due to a fault event and the normal operational current waveform of a grid can be modified by fault events and associated recloser opening or closing events. Thus, the sensor devices measure an identify changes in the current waveform that correspond to a fault event or associated fault opening or closing event. Determining both the fault and recloser events times are advantageous for the localization process to mitigate effects of clock drift between a plurality of sensor devices. FIG. 10 shows a change in current caused by the fault and recloser events and FIG. 11 shows a magnified view of change in current caused by the fault event.

One method of detecting fault or recloser events is by establishing a threshold. Fault and recloser events usually cause a sudden change in current (as shown in FIGS. 10 and 11). These changes place the measured current outside of an expected norm. Therefore, thresholds can be established with triggers to detect when the current deviates from some normal operational current. Detecting the fault event would then be achieved by a comparison between the measured current and a fault threshold value. If the measured current exceeds this value, then a fault (fault signal) is being detected and a fault trigger can be fired. This fault trigger will cause a time log to be made (for creating the fault key). The fault trigger can also place the system into a recloser event search state which then focuses on the detection of the expected recloser event. To detect the recloser signal a threshold can also be established for detecting either the sudden drop in current that occurs when a recloser opens or the sudden increase in current when the recloser closes which can then fire a recloser trigger. The recloser trigger will result in a time log to be made (for synchronizing and fault key generation) and can also be used to confirm the previously logged fault event (as a recloser signal only occurs if a fault has occurred). These triggers can be set in off-the-shelf sensor components that commonly provide threshold monitoring functionality. These triggers can also be created with custom software components for the system during its construction.

Alternative methods are available to identify fault and recloser currents (signals/events). Wavelets have been used extensively in research to identify fault current profiles and determine when a fault event has occurred. It is also possible to utilize machine learning techniques such as neural networks to detect fault and recloser events when monitoring current. Generally, these methods would use a profile for fault and recloser current signals and monitor the current for matches to these profiles. A match would then indicate the presence of the corresponding event and its time can be logged for the localization process. These options (not necessarily limited to those mentioned here) can be tested to determine the most effective fault detection mechanism to employ.

A micro PC allows the fault and reclosure events to be taken from the current sensor and labelled with that sensor's ID in the grid. This is done using a trigger function. The trigger function is configured to detect abnormal conditions in the electrical current caused by faults and recloser operations. It is set to record all the data just before and after an abnormal state has been detected. This data is then filtered and analyzed to determine the exact time the current changed from its normal operation to the fault current or recloser operation current. It is this initial change that captures the incident wave times of both the fault and recloser whose timing is used in the localization process.

A communications board is responsible for transmitting the recloser and fault incident wave times to the localization module. Any communication protocol can be used to transfer the data from the sensor devices to the localization module since the data from a sensor device consists of two timestamps and the sensor device identifier. This small amount of data allows for various available protocols and communication techniques to be employed.

### Experimental Example 1.2: Web/User Interface Module

The User Interface Module is used to provide information about the electrical grid to the fault localization system and receives the results of fault localization.

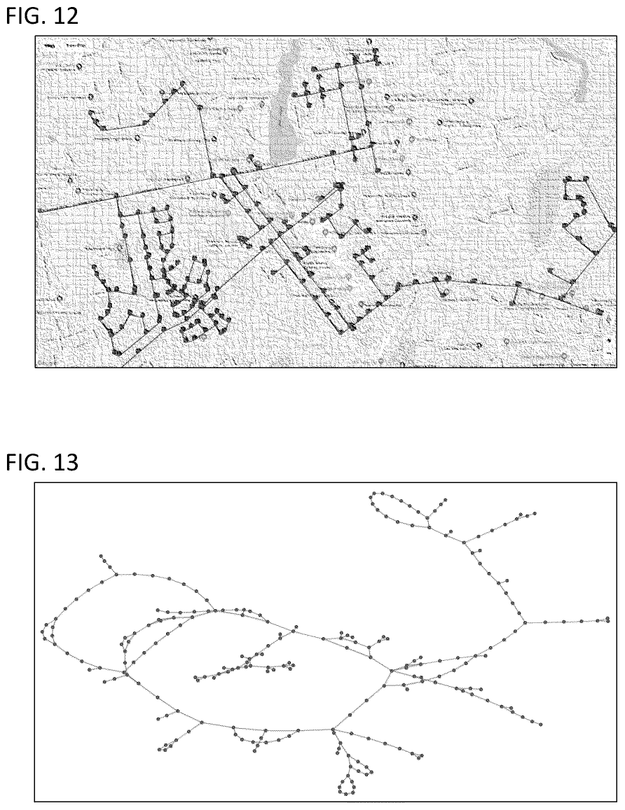

Google maps API was used to develop a JavaScript module that allows a user to simply click on the map to draw the layout of any electrical grid. Each click creates a node which allows the GPS coordinates of the cables to be captured along with the locations of any components like reclosers. For example, FIG. 12 shows a distribution grid mapped in google maps.

Each of the nodes displayed is given a unique identifier and its GPS coordinates are recorded. In addition to this, all of a node's neighbors are recorded using their identifiers. After the grid has been mapped out a JSON file is generated. The JSON file contains a single JSON object that represents a list of nodes, where node is associated with a unique identifier, GPS coordinates and a list of neighbors. This object is used to create the graph object used by the remainder of the system's functions.

The fault location report is used to show the user the final fault location calculated by the localization module. The google maps grid drawn by the user is reloaded onto the map after the fault location is determined. Once the map is displayed the fault location is placed on the map, providing a real-world location that can then be used by a repair team to service the fault.

The fault location displayed can be made up of a highlighted edge (line between two nodes, referred to as the fault edge) and a single point on that highlighted fault edge. The single point is the actual fault location. The built-in functionality of google maps allows a user to look at the street view of that location to determine if and what component or environmental element is at that location (such as trees etc.).

### Experimental Example 1.3: Calibration Module

The calibration module is the first of two MATLAB modules used by the system (the second being the localization module). Before the system can localize faults, it must be provided with data in the form of the node file from the Google maps interface (containing a list of nodes and their neighbors). This data is then used to optimize the location of all sensors on the grid. The edge keys which provide the expected time data used for localization can then be created using the graph object and the sensor locations.

The required data is loaded from the file prepared by the Google maps input interface and is used to create a graph object (for example, as shown in FIG. 13) with weighted edges where the weight is the length of the edge. Each node represents a selected point in the electrical grid. The file contains a list of nodes and their GPS coordinates, each with a list of its neighbors. The function that creates the graph object iterates over each of these nodes and adds an edge between it and each of its neighbors. The GPS coordinates are then used to determine the Euclidean distance in meters for each edge. These distances between a node and its neighbors are then used as weights for the respective edges.

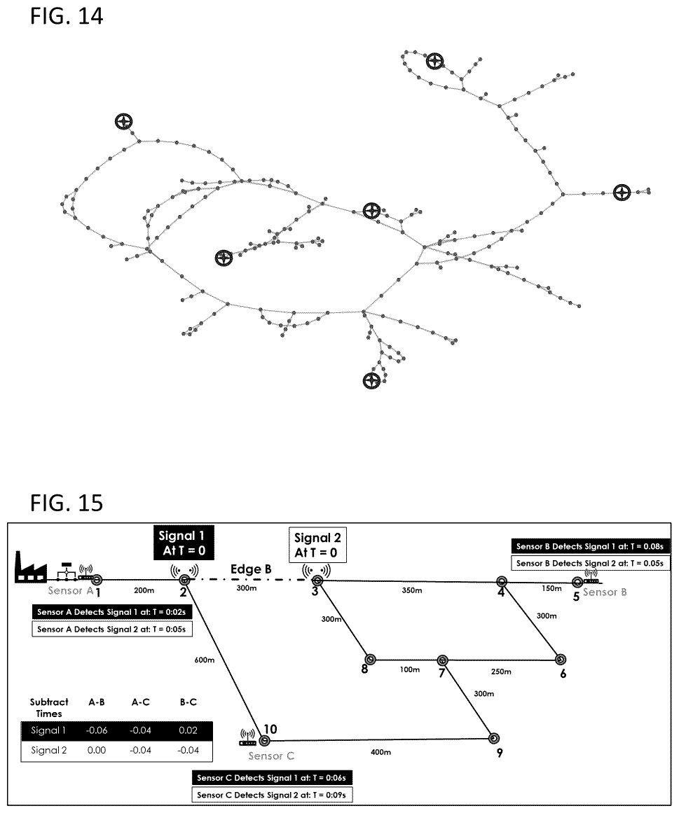

The graph is used to determine optimal sensor locations. The best locations for sensors are determined by a maximization function. The function maximizes the number of edges with a unique key. The optimization process starts with the placement of two sensors (each one placed at a node) so that their locations provide the maximum number of edges with unique keys. For every additional sensor to be placed, the existing sensors nodes (those that have been previously placed) are used along with all remaining nodes to determine which of the remaining nodes provides the maximum increase in edges with unique keys. This process is repeated until the desired number of sensors have been placed on a node. The system is set up to calculate and recommend the number of sensors needed to monitor the grid and the optimal placement of the sensors. For example, FIG. 14 shows a MATLAB graph feeder with optimized sensor locations (circled stars). The system however can still operate and localize faults without the optimal number or placement of sensors to account for budget limitations and sensor placement restrictions. The system can adjust to an existing budget of sensors and maximize the use of the sensors available.

The edge keys provide expected time data references for the fault localization technique. Fault localization occurs by comparing time data derived from fault event time data to the expected time data provided by edge keys. Each edge key effectively establishes a time window (or time range) within which a signal originating from a given edge is expected to be detected by each of a plurality of sensors. Each edge key is a set of delays between the time it takes signals occurring at both ends of a given edge to reach every sensor on the grid. The process for generating an edge key is as follows (referring to FIG. 15):

1. Select one end of an edge (node 2 from edge B in FIG. 15).

2. Calculate the time each sensor would detect a signal (signal 1 in FIG. 15) originating from this end of the edge (node 2).

3. Calculate the delay between the signal arrival times (of signal 1 in FIG. 15) to each sensor (recoded in row “Signal 1” and column A-B, A-C and B-C).

4. Repeat process for the opposite end of the edge (which is node 3 and signal 2 in FIG. 15)

The result is an edge key, which is a 2 by k matrix, where k is the number of unique combinations of pairings between the sensors given by Equation 1, n is the number of sensors placed in the grid and the 2 is the result of performing the calculation for both ends of the edge. Each end allows the generation of delays that delimits the limits of the time window (ie., upper and lower bounds of a time range) for each edge.

$$k = ( n ( n - 1 ) ) / 2 \qquad ( Eq . 1 )$$

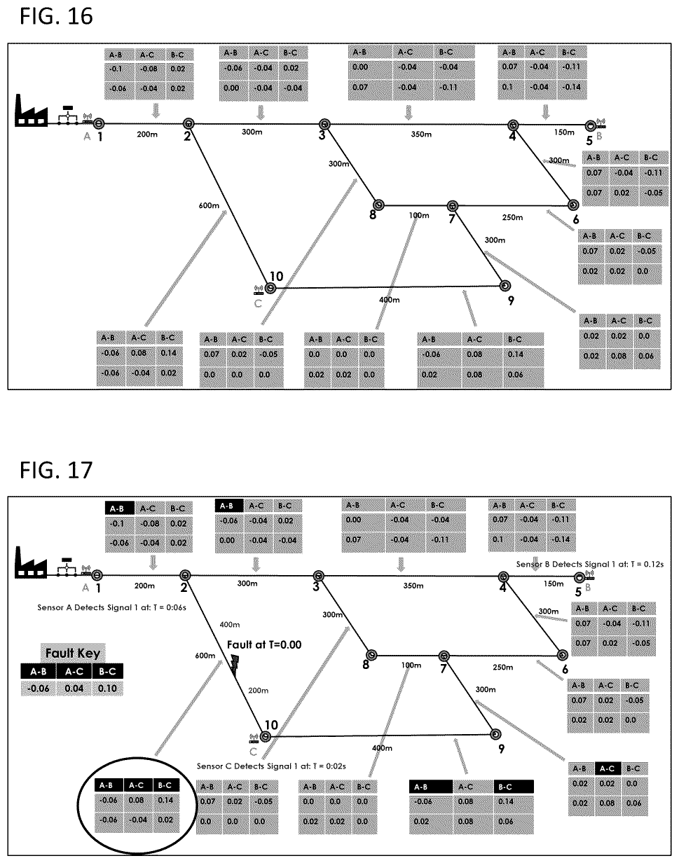

This 2 by k matrix is the edge key used during the localization process to identify the origin of a signal. This process is repeated for every edge in the graph/grid object. Each edge in the graph would now have a 2 by k-element key as shown in FIG. 16. The upper and lower bounds for each pairing's delay (time window) may then be sorted so that the greater number (upper bound) is in the top row (not shown in FIG. 7).

### Experimental Example 1.4: Localization Module

The localization module is responsible for integrating all the data provided by the other modules in order to localize faults. It uses the graph object and the edge keys created by the calibration module. It also uses the fault and recloser incident wave times from each sensor device (provided by the sensor device module) when a fault occurs. The localization module is brought online after the system has been calibrated.

The fault key is compared to each edge key to determine the location of the fault in the grid. The fault key is a set of delays between time each sensor detects the fault (fault incident wave). Therefore, the fault localization process requires the times that the fault incident wave reaches each sensor. Due to each sensor operating with its own clock, the various sensor clocks may not be synchronized to a degree of accuracy required. The accuracy required is often on the scale of micro or nanoseconds (1×10-9) seconds. As such, the recloser event can be used in aligning the fault incident waves times across multiple devices. It is the incident waves created by the recloser that allow a globally synchronized series of events to be established from many separately timed events. The following steps cover the fault key generation process.
Once a fault incident wave has been detected by a sensor it is logged using that sensor's clock (Fault Detection Time (FDT)).
When a fault occurs the recloser disconnects the line in an attempt to clear the fault (in case it was a transient fault). Which also sends out an incident wave that is logged by the sensors (Recloser Detection Time (RDT)).
Each sensor device calculates the delay between its FDT and RDT (Fault-Recloser Delay (FRD)).
The location of the recloser is known and by extension the time it would take the RDT to reach each sensor (Recloser Travel Time (RTT)) on a global clock).
Add the RTT to the FRD for each sensor to align the fault times on a global clock.

Equation 2 shows the translation of the process into an equation. Where 1 and 2 are a pair of sensors and FDT, RDT and RTT are arrays containing the corresponding time data for each sensor as explained in the fault key generation process.

$$F K ( 1 , 2 ) = ( ( F D T [ 1 ] - R D T [ 1 ] ) + R T T [ 1 ] ) - ( ( F D T [ 2 ] - R D T [ 2 ] ) + R T T [ 2 ] ) \qquad ( Eq . 2 )$$

The fault key has k elements given by Equation 1 representing the number of pairings for all n sensors. Each element of the fault key now represents the FDT delay between a pair of sensors on a global clock. Equation 2 shows how an element is created for a given pair of sensors. This is done for all k pairings to create a complete fault key. The fault key is then used to determine the location of the fault in the grid.

Once the fault key has been calculated, the fault key is communicated to the edge key examination component to determine which edge key matches the fault key. The edge that matches is identified as the edge from which the fault originated. Each element in the fault key is compared to its corresponding element in the edge keys. FIG. 17 shows this process, here the fault occurs at time T=0. The fault key is generated and each element of the fault key is compared to the corresponding edge key (delimiting the upper and lower bounds or time windows). If each element of the fault key falls within the bounds for an edge key that edge is selected as the fault edge. In FIG. 17 there were four edge keys that had partial matches. However, the circled edge key is the only one where all elements of the fault key fall within their corresponding bounds in the edge key.

Once the fault edge has been found that edge will be sent back to the user via the google maps interface. The fault edge may be marked as desired for convenience of display to the user, for example the fault edge may be highlighted in red. The final step in the localization process is to determine a location within the fault edge where the fault is likely to be found. To determine the location within the fault edge a column of the corresponding edge key is required (this is the same edge key that matched the fault key). The column selected has one requirement, that the upper and lower bounds of that column not be the same. Continuing with the example consider the selected edge key in FIG. 17. Choosing column 2 which is the pair for sensor A and C we have the upper bound of 0.08 s and the lower bound of −0.04 s. Recall that these were created from node 10 and 2 respectively and the distance along this edge is 600 meters. Also recall that the fault key value for sensor A and C is 0.04 s. With this information the location along the edge can be determined using Equation 3.

$$Distance ( node ) = abs ( FaultEdgeKey ( A , C ) - FaultKey ( A , C ) * \qquad ( Eq . 3 )$$

$$( \frac{1}{PropagationSpeed} ) / 2$$

Where node is given as either of the nodes of the fault edge. A-C represent a sensor pair A-C where the upper and lower bounds are not the same. FaultEdgeKey(A,C) is the edge key bound created by the given node for the sensor pair A-C, FaultKey(A,C) is the fault key element for the sensor pair A-C and propagationSpeed is the time it takes a signal to travel one meter. Equation 4 shows the use of Equation 3 for the specific example shown in FIG. 17.

$$Distance ( 2 ) = abs ( - 0.04 - 0.04 ) * ( \frac{1}{0.0001} ) / 2 = 400 \qquad ( Eq . 4 )$$

The result of Equation 4 is 400 m meaning that the fault is 400 meters away from node 2 on the fault edge (edge 2-10). Once the location along the fault edge is determined the fault location will also be displayed with a suitable visual indicator or symbol, for example a black or red hazard symbol, in google maps.

In the case where the recommended number of sensors are not used there are some effects on the localization results. These effects emerge during the Edge Key examination to find a match to the fault key. If the correct number of sensors and their placement is done, there will only be one edge key that matches the fault key. Without the correct number of sensors, it is possible (only in some cases) for multiple edges to match the fault key. This would only occur if the location of the fault happens to be in a location that is not covered by the current number of sensors in the grid. In this case, the system would return an area or areas where the fault will be found. This area (or areas) is made up by all of the edges that match the fault key. The system is still able to eliminate as much edges as possible with the limited sensors, allowing the faulty area to be highlighted. As mentioned, the system can determine all locations in the grid where there is inadequate coverage beforehand and advise the correct number and location of sensors. The user would therefore know beforehand where the grey areas in the grid are where a sensor may be needed. If the fault does not occur in these grey areas the system with only find one matching edge and localization would proceed as normal.

### Experimental Example 1.5: Evaluation

Testing was performed on each component in the calibration module and the localization module. The goal of these initial tests was to determine if the system would be able to localize faults when provided the correct information from the sensor devices and user (grid layout etc.). To test the components in these modules, ten random fault locations were used. In each test a node in the graph object was chosen as the fault location. Once a node was selected as a fault node, the fault key was generated by converting the distances (from the fault node to all the sensor nodes) to times. This simulated fault key (using the graph rather than sensor data) was then communicated to the fault localization algorithm.

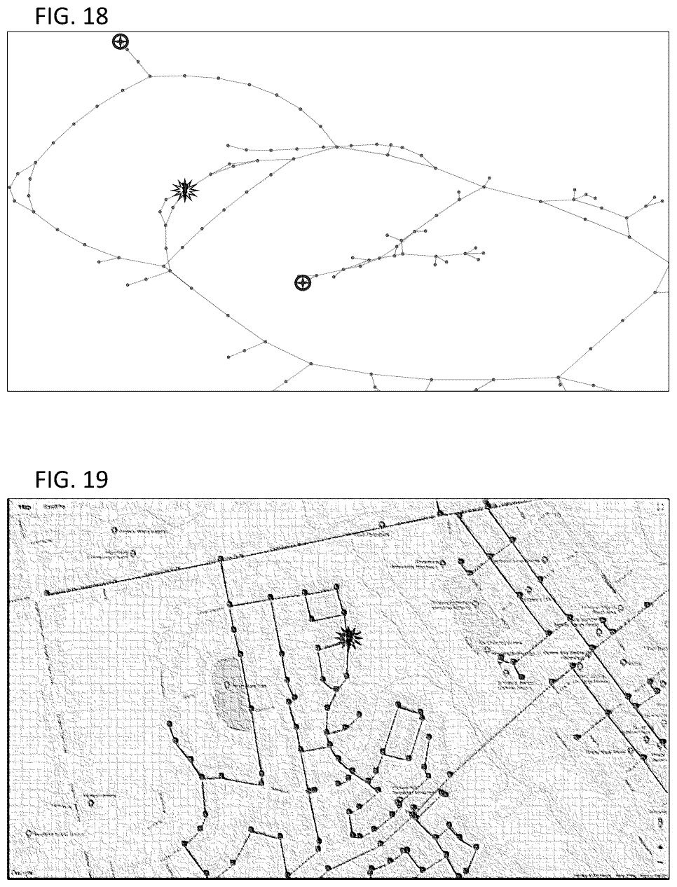

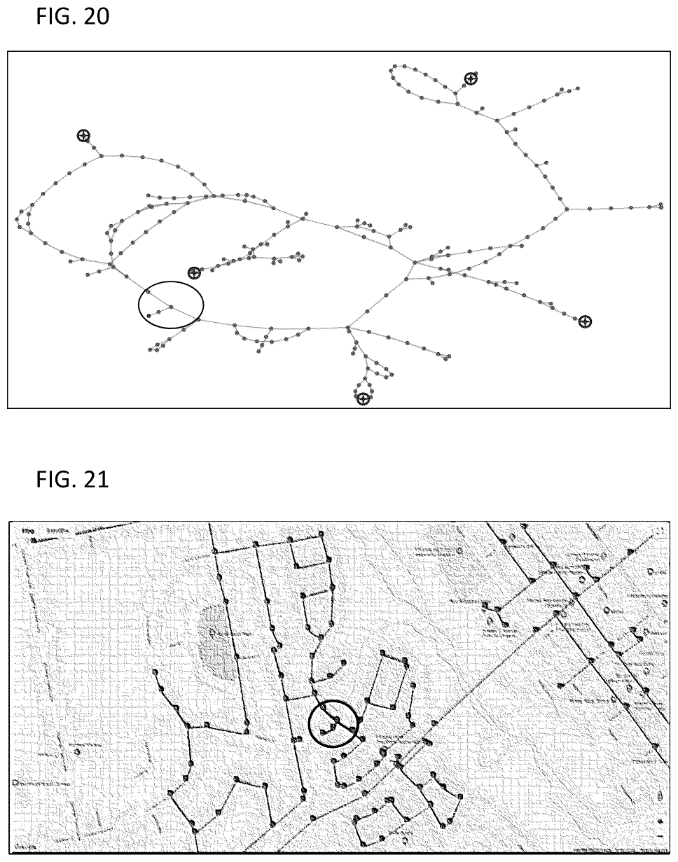

The testing at this stage was successful and the correct fault edge was selected along with the correct fault location indicated within the graph object as shown in FIG. 18 for example, and the fault location correctly displayed on a Google maps interface as shown in FIG. 19 for example. Test cases were also done when the recommended number of sensors was not used. In these cases, the correct group of edges was highlighted that consistently contained the fault node that was selected (as shown for example in FIG. 20 and FIG. 21).

Secondary testing involved the sensor module code and the google maps module output. This testing used Simulink to simulate faults on the actual electrical grid feeder used to calibrate the system. These tests were done to confirm the localization process can be executed using all modules except the sensors and the final output interface. The process below shows how this testing was conducted:

1. Create the map of an electrical grid feeder using the google maps interface.

2. Submit the map for it to be automatically converted into a JSON file.

3. Call the MATLAB calibration module with the JSON file (which determines the optimal sensor locations and edge keys).

4. Select a fault location using the google maps interface.

5. Create a SIMULINK model of the electrical grid and the sensors.

6. Simulate the fault and recloser events and record these events at each sensor.

7. Examine the sensor data using the rate of change in current to detect the incident wave time for the fault and recloser events at each sensor.

8. Create the fault key from the incident wave times recorded at each sensor.

9. Call the MATLAB localization module providing the fault key.

10. Display the fault edge and fault location using the MATLAB graph object.

Secondary testing was performed by creating an electrical feeder and then selecting a fault location in the google maps interface. This was then fed into the system which automatically calibrated itself. Using the fault location given, steps 5 to 8 were done using a SIMULINK model of the grid. SIMULINK allowed the system to be tested without the use of actual sensors placed on the grid. The model represented the electrical grid and its components and simulated the traversal of the fault and recloser incident waves through the grid. The fault key was then created from this data and fed to the localization module. The localization module identified the fault edge and the fault location on that edge successfully with an error of less than 20 meters.

### Experimental Example 2

This experimental example validates a method of synchronizing sensor devices deployed in an electrical grid. The proposed method focuses on sensor device synchronization specifically for localizing faults on distribution networks. It analyses the travelling waves that are present on the electrical grid at and around the time of the fault. It is a synchronization method which uses external signals to synchronize the fault events detected by the sensor devices without reliance on accuracy of clocks used in each sensor device.

This synchronization method allows synchronization of data collected by sensor devices at multiple locations in the distribution grid without reliance on accuracy of the clocks used in each sensor device. Faults often manifest themselves as a sudden drop or surge in the current. Before the sudden drop or surge an incident, wave is generated and travels throughout the grid. This is followed by other waves that travel as the result of incident wave reflecting off endpoints. Sensors can be used to detect the incident wave. With this information, knowledge of the distance between sensors and propagation speed it is possible to determine the distance to a fault.

A fault is detected by reclosers, relays, fuses and breakers. The area that the fault occurs in is turned off by the reclosures and relays. Once the location of the fault is determined and fixed, power can be restored. In FIG. 3, a fault occurs in the area powered by phase 2 (the blue feeder). When the fault is detected by the recloser, it opens and shuts of power to the entire area powered by that phase. There is no knowledge of the location of the fault. It is only known that something has gone wrong and caused the power to be turned off. If this area covers a two- or four-mile area, that entire area has to be visually inspected. This challenge is compounded by the fact that some of these areas of the grid are buried underground.

For a fault to be localized and fixed the presence of a fault must first be detected. With respect to fault detection there are two types of faults: High Impedance Faults (HIFs) and Low Impedance Faults (LIFs). HIFs are more difficult to detect since the fault can mimic the normal operation of the grid.

A LIF allows large amounts of electricity to flow through it. The electrical grid uses sensor devices that detect LIF currents by monitoring for abnormal currents or voltages present on the line. An abnormal current is identified as an interruption(drop) or surge in the flow of current. FIG. 22 shows the current before and during a fault on a single phase. These drops and surges that constitute an abnormal current are preceded by a set of travelling waves that propagate through the grid. A fault event (like a downed power line) creates a travelling wave referred to as the incident wave. This incident wave travels from the fault point in all directions along the power cable and through the network. This travelling wave is the first peak seen in the magnified view shown in FIG. 22. The remaining peaks seen are the result of that incident wave bouncing or reflecting off various components in the electrical grid. These echo waves are referred to as reflected waves. The incident wave and reflected waves generated by a fault are referred to as a fault signal.

The method presented in this work can be categorized as an external signal synchronization method based on use of signals generated by components of the electric grid. Sensors detect the signals from these components. The external signals are the set of travelling waves emitted from the recloser on the electrical grid. In distribution feeders there is a recloser device that is activated whenever a fault is detected. Typically, reclosers are located at the beginning of a feeder and therefore control large distribution areas. The recloser is responsible for clearing (removing) any temporary faults. These are faults that can be cleared by de-energizing the line for a short period of time. An example of a temporary fault is a conductive material making brief contact with a power cable creating an arc through which electrical current flows. De-energizing the power cable will break the electrical arc and end the erroneous flow of electricity. When an erroneous fault current is detected the recloser opens and disconnects power to the feeder to give the temporary fault time to clear (in our example break the flow of electricity through the arc). After a predefined time (usually a few seconds), the recloser then reconnects the feeder. If the fault current is then back within normal range, the recloser leaves the power cable/line connected. If the recloser still detects a fault current it will disconnect the feeder again. The number of times the recloser will attempt to clear the fault is defined by the power company but is typically three times.

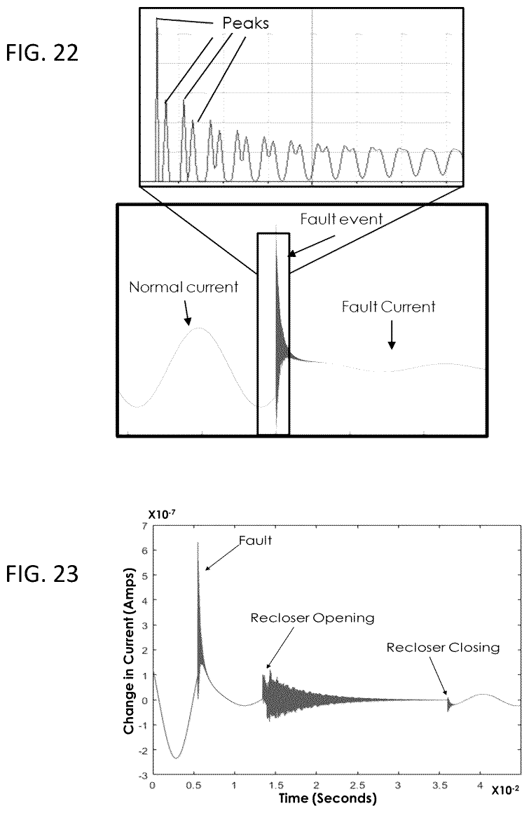

The fault itself causes the first set of travelling waves(fault signal). After this is detected, an attempt by the recloser to clear the fault results in the insertion of two more sets of travelling waves(recloser signals) into the feeder. All three sets of travelling waves cause fluctuations in current as seen in FIG. 5. The difference between a fault's set of travelling waves (fault signal) and the recloser's first and second sets of travelling waves (recloser signals) is that the feeder will still have current flowing through it (in the form of abnormal current or fault current) after a fault. However, after the first recloser signal (when opening), the current is reduced to zero and after the second recloser signal (when closing) the flow of current resumes. FIG. 23 shows the measured current just before and during a fault and the corresponding recloser activation.

Normal operating current can be observed from 0 to 0.5. This is the expected sine wave from the natural flow of power from the power generation facility. The effect of the fault is seen at time 0.5. Here we can see that the current suddenly changes significantly but some power is still flowing (fault current) up until 1.3 seconds. At time 1.3 the recloser activates (by opening and halting the flow of power) and de-energizes the feeder creating another disturbance in electrical current. The recloser opening causes the abnormal fault current to drop to zero (the first recloser signal). After the line is de-energized at time 3.52 the recloser reconnects the power and a surge in current is then detected as power resumes its flow (the second recloser signal). In this case the current is still abnormal (reduced in this case) and the recloser will repeat the process or remain open and permanently disconnect the power.

### Experimental Example 2.1: Using Reclosers for Synchronization and Fault Localization

A recloser incident wave may be leveraged to synchronize an incident wave from the fault detected by the sensor devices. The recloser's travelling waves at a wave propagation speed s provides a way to localize a fault, f, from sensor A which is calculated using the Equation 5.

$$dist ( A , f ) = ( \frac{{delay}_{B}^{A} - ( ( {delay}_{f}^{R ,} ( B ) - {delay}_{A , B}^{R} ) - {delay}_{f}^{R} ( A ) )}{2} ) / s \qquad ( Eq . 5 )$$

A component of Equation 5 is the distance between sensor A and B, dist(A,B) and the time it takes a wave to travel from A to B (expressed as delay_{B}^{A}).

The locations of sensors and reclosures on the grid are known and hence the distances between them are known. The propagation speed of waves s on the given line is also known. For example, with this information the time it takes for the recloser's travelling waves to reach sensor A can be calculated using Equation 6.

$${T}_{A}^{R} = dist ( R , A ) * s \qquad ( Eq . 6 )$$

where dist(R,A) is the distance between the recloser and sensor A, and s denotes the propagation speed of waves on the given line. The relationship between distance and delays allows us to measure delays and then convert delay values to distances.

The delay between the arrival times of the recloser wave to each sensor can be calculated by Equation 7.

$${delay}_{A , B}^{R} = {T}_{A}^{R} - {T}_{B}^{R} \qquad ( Eq . 7 )$$

Thus, the delay value represents the difference between the times that sensors A and B detect the reclosure signal.

Equation 8 is used to calculate the time delay between the recloser wave and the fault wave measured by a single sensor, x.

$${delay}_{f}^{R} ( x ) = {T}_{x}^{R} - {T}_{x}^{f} \qquad ( Eq . 8 )$$

### Experimental Example 2.2: Evaluation

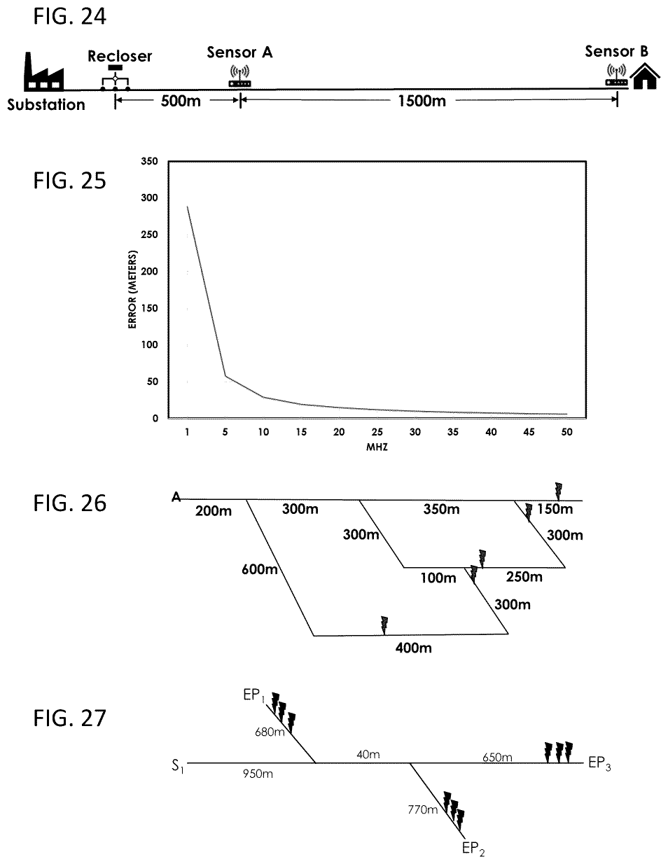

To determine the effectiveness of this method we simulated a distribution line with two sensors as shown in FIG. 24. One end is connected to a substation providing power, which then flows along the line through the recloser and continues to a customer.

Using the known distances, the propagation delay of the line and Equation 5 faults occurring between the two sensors A and B can be localized. Testing involved the simulation of an actual fault and applying the localization method in this scenario to determine its effectiveness. For this testing Simulink is used to create a model of a distribution line using FIG. 6 as the template. The recloser and sensors are added, and a fault is then simulated between the two sensors.

For the initial proof of concept, an arbitrary sample rate of 5 Mhz was chosen. This sample rate determines how often the electrical current is measured at each sensor's location. The expected timing of the reclosure and fault wave arrival times was calculated and then compared with the arrival times recorded during the simulation. This was done for eight measurements of recloser and fault waves. Eight tests allowed two faults to be simulated on the rising and falling segments of positive and negative current values generated by alternating current. These timing errors were calculated into distances so that the impact of the timing errors on the final fault location can be clearly seen. The error in the measurement of arrival times of the recloser wave at 5 Mhz resulted in an average error of 57.64 meters to be introduced into the calculation of fault location. The error in the measurement of arrival times of the fault incident wave at 5 Mhz resulted in an average error of 70.17 meters to be introduced into the calculation of fault location.

These errors in recloser and fault wave measurements due to a 5 Mhz sample rate resulted in the final fault location calculations for the tests to be from 23 meters up to 168 meters. With a sample rate of 5 Mhz there is a gap of 2e-7 seconds between samples. This means that the current change that is indicative of an incident wave could be detected up to 2e-7 seconds after its arrival. This is because in a worst-case scenario, if the sample is taken just before the current changes, the entire 2e-7 seconds would pass before the next sample is taken and the change in current is detected. The impact of such a delay can be seen when using the speed a signal travels on a given cable. The speed of a signal through the cable in our scenario is around 288 million meters per second. When converted to distance that 2e-7 seconds translates to 57 meters. This means that at 5 Mhz every sample can have an error of 57 meters. As two samples are taken, 114 meters of error can be introduced due to the sample rate.

The optimal sample rate is dependent on the signal speed of the cable and the desired error range. More practically, this would also include the cost of the sensor device, as devices with higher sample rates are more expensive.

FIG. 25 shows the decrease in error achieved by the increase in sample rate. In FIG. 25 the improvement of error for sample rate increase quickly diminishes requiring large increases of sampling rate for a small reduction in error.

In a real-world implementation, the sample rate chosen may vary based on the signal speed of the cable used and the cost of the sensor devices. In our tests 20 Mhz is chosen because an error of 14 meters provides a high level of accuracy for the computational and storage cost of running a simulation at that sample rate.

Using 20 MHz as the sampling rate should allow faults to be consistently localized with small errors. A small error is considered less than 50 meters. This is because the goal is to either place a user at the fault location or place them within line of sight of the actual fault location.

Ten tests were conducted with a sample rate of 20 Megahertz. Random fault locations were placed along a cable and simulated in Matlab. The delay between the fault signal arriving at each sensor was calculated using the recloser to synchronize. The delay was then used to determine the fault location. The results are shown in Table 1. The average error of these tests was 15.73 meters with a maximum error of 26.51 meters.

TABLE 1
Test Results at 20 MHz.

| Measured Distance (meters) | Actual Distance (meters) | Error (meters) |
|---|---|---|
| 1289.63 | 1300.00 | 10.37 |
| 1181.56 | 1200.00 | 18.44 |
| 2377.52 | 2400.00 | 22.48 |
| 1887.61 | 1900.00 | 12.39 |
| 1988.47 | 2000.00 | 11.53 |
| 2074.93 | 2100.00 | 25.07 |
| 987.03 | 1000.00 | 12.97 |
| 489.91 | 500.00 | 10.09 |
| 792.51 | 800.00 | 7.49 |
| 3573.49 | 3600.00 | 26.51 |

### Reference List for Experimental Example 2

1 Marguet, R.: ‘Improved fault localization method for electrical power distribution networks’, 2015
2 Saha, M., Provoost, F., and Rosolowski, E.: ‘Fault location method for MV cable network’, 2001
3 Das, S., Kulkarni, S., Karnik, N., and Santoso, S.: ‘Distribution fault location using short-circuit fault current profile approach’, in Editor (Ed.)\hat{ }(Eds.): ‘Book Distribution fault location using short-circuit fault current profile approach’ (2011, edn.), pp. 1-7
4 Karnik, N., Das, S., Kulkarni, S., and Santoso, S.: ‘Effect of load current on fault location estimates of impedance-based methods’, in Editor (Ed.)\hat{ }(Eds.): ‘Book Effect of load current on fault location estimates of impedance-based methods’ (2011, edn.), pp. 1-6
5 Takagi, T., Yamakoshi, Y., Yamaura, M., Kondow, R., and Matsushima, T.: ‘Development of a New Type Fault Locator Using the One-Terminal Voltage and Current Data’, IEEE Transactions on Power Apparatus and Systems, 1982, PAS-101, (8), pp. 2892-2898
6 Crossley, P. A., and McLaren, P. G.: ‘Distance Protection Based on Travelling Waves’, IEEE Transactions on Power Apparatus and Systems, 1983, PAS-102, (9), pp. 2971-2983
7 Magnago, F. H., and Abur, A.: ‘Fault location using wavelets’, IEEE Transactions on Power Delivery, 1998, 13, (4), pp. 1475-1480
8 Hizam, H., and Crossley, P. A.: ‘Single Ended Fault Location Technique On a Radial Distribution Network Using Fault Generated Current Signals’ (2006. 2006)
9 Girgis, A. A., Fallon, C. M., and Lubkeman, D. L.: ‘A fault location technique for rural distribution feeders’, IEEE Transactions on Industry Applications, 1993, 29, (6), pp. 1170-1175
10 Jun, Z., Lubkeman, D. L., and Girgis, A. A.: ‘Automated fault location and diagnosis on electric power distribution feeders’, IEEE Transactions on Power Delivery, 1997, 12, (2), pp. 801-809
11 Seung-Jae, L., Myeon-Song, C., Sang-Hee, K., Bo-Gun, J., Duck-Su, L., Bok-Shin, A., Nam-Seon, Y., Ho-Yong, K., and Sang-Bong, W.: ‘An intelligent and efficient fault location and diagnosis scheme for radial distribution systems’, IEEE Transactions on Power Delivery, 2004, 19, (2), pp. 524-532
12 Gabr, M. A., Ibrahim, D. K., Ahmed, E. S., and Gilany, M. I.: ‘A new impedance-based fault location scheme for overhead unbalanced radial distribution networks’, Electric Power Systems Research, 2017, 142, pp. 153-162
13 Estebsari, A., Pons, E., Bompard, E., Bahmanyar, A., and Jamali, S.: ‘An improved fault location method for distribution networks exploiting emerging LV smart meters’, in Editor (Ed.)\hat{ }(Eds.): ‘Book An improved fault location method for distribution networks exploiting emerging LV smart meters’ (2016, edn.), pp. 1-6
14 Pourahmadi-Nakhli, M., and Safavi, A. A.: ‘Path Characteristic Frequency-Based Fault Locating in Radial Distribution Systems Using Wavelets and Neural Networks’, IEEE Transactions on Power Delivery, 2011, 26, (2), pp. 772-781
15 Wen, F., and Chang, C. S.: ‘A new approach to fault diagnosis in electrical distribution networks using a genetic algorithm’, Artificial Intelligence in Engineering, 1998, 12, pp. 69-80
16 Srinivasan, D., Cheu, R. L., Poh, Y. P., Kim, A., and Ng, C.: ‘Automated fault detection in power distribution networks using a hybrid fuzzy±genetic algorithm approach’, 2000
17 Trindade, F. C. L., Freitas, W., and Vieira, J. C. M.: ‘Fault Location in Distribution Systems Based on Smart Feeder Meters’, IEEE Transactions on Power Delivery, 2014, 29, (1), pp. 251-260
18 Trindade, F. C. L., and Freitas, W.: ‘Low Voltage Zones to Support Fault Location in Distribution Systems With Smart Meters’, IEEE Transactions on Smart Grid, 2017, 8, (6), pp. 2765-2774
19 Skumit, T., and Z, E.: ‘Open Phase Fault Localization in a Medium Voltage Distribution Grid Using Smart Meters’, in Editor (Ed.)\hat{ }(Eds.): ‘Book Open Phase Fault Localization in a Medium Voltage Distribution Grid Using Smart Meters’ (2019, edn.), pp. 1-6
20 Sapountzoglou, N., Raison, B., and Silva, N.: ‘Fault Detection and Localization in LV Smart Grids’, in Editor (Ed.)\hat{ }(Eds.): ‘Book Fault Detection and Localization in LV Smart Grids’ (2019, edn.), pp. 1-6
21 Viswanathan, S., Tan, R., and Yau, D. K. Y.: ‘Exploiting Power Grid for Accurate and Secure Clock Synchronization in Industrial IoT’, in Editor (Ed.)\hat{ }(Eds.): ‘Book Exploiting Power Grid for Accurate and Secure Clock Synchronization in Industrial IoT’ (2016, edn.), pp. 146-156
22 Elson, J., Girod, L., and Estrin, D.: ‘Fine-grained network time synchronization using reference broadcasts’, SIGOPS Oper. Syst. Rev., 2002, 36, (SI), pp. 147-163
23 Ganeriwal, S., Kumar, R., and Srivastava, M. B.: ‘Timing-sync protocol for sensor networks’. Proc. Proceedings of the 1st international conference on Embedded networked sensor systems, Los Angeles, California, USA2003 pp. Pages
24 Mikl, #243, Mar, s., #243, ti, Kusy, B., Simon, G., #193, L, k., #233, and deczi: ‘The flooding time synchronization protocol’. Proc. Proceedings of the 2nd international conference on Embedded networked sensor systems, Baltimore, MD, USA2004 pp. Pages
25 Maroti, M., Kusy, B., Simon, G., and Ledeczi, A.: ‘The flooding time synchronization protocol’. Proc. Proceedings of the 2nd international conference on Embedded networked sensor systems, Baltimore, MD, USA2004 pp. Pages
26 Chen, Y., Wang, Q., Chang, M., and Terzis, A.: ‘Ultra-low power time synchronization using passive radio receivers’, in Editor (Ed.)\hat{ }(Eds.): ‘Book Ultra-low power time synchronization using passive radio receivers’ (2011, edn.), pp. 235-245
27 Li, L., Xing, G., Sun, L., Huangfu, W., Zhou, R., and Zhu, H.: ‘Exploiting FM radio data system for adaptive clock calibration in sensor networks’. Proc. Proceedings of the 9th international conference on Mobile systems, applications, and services, Bethesda, Maryland, USA2011 pp. Pages
28 Hao, T., Zhou, R., Xing, G., and Mutka, M.: ‘WizSync: Exploiting Wi-Fi Infrastructure for Clock Synchronization in Wireless Sensor Networks’, in Editor (Ed.)\hat{ }(Eds.): ‘Book WizSync: Exploiting Wi-Fi Infrastructure for Clock Synchronization in Wireless Sensor Networks’ (2011, edn.), pp. 149-158
29 Rowe, A., Gupta, V., and Rajkumar, R.: ‘Low-power clock synchronization using electromagnetic energy radiating from AC power lines’. Proc. Proceedings of the 7th ACM Conference on Embedded Networked Sensor Systems, Berkeley, California2009 pp. Pages
30 Li, Z., Li, C., Chen, W., Dai, J., Li, M., Li, X.-Y., and Liu, Y.: ‘Clock calibration using fluorescent lighting’. Proc. Proceedings of the 18th annual international conference on Mobile computing and networking, Istanbul, Turkey 2012 pp. Pages 31 ‘Ontario Electricity Provider’, 2018

### Experimental Example 3

Experimental Example 3 provides an efficient method of localizing a fault on an electrical distribution grid while maintaining a high level of accuracy. First the grid is broken down into segments, each with a unique identifier. The solution then analyses the travelling waves that are present on the electrical grid at the time of the fault. These signals are measured by sensors at multiple locations and used to generate a key that is then utilized in conjunction with a segmented graphical representation of the electrical distribution grid to determine the location of the fault. The results show that the proposed approach is effective.

Fault localization approaches for distribution grids can be categorized as impedance-based or as travelling waves [1].

Andrade et al [3] describe impedance-based methods to be a calculation of distance that uses the loop that is created between the fault and the point on the line that is being measured. Impedance-based methods [1] include positive reactance ([4-6]), loop reactance [7] and the Takagi equation [8].

There is existing work on the application of impedance-based methods in the distribution grid (e.g., [8], [9], [10], [11], [12]). However, Mwifunyi et al [13] notes that these impedance methods use constant impedance load modelling which is somewhat detached from the variability of the load in a real distribution grid, and may provide multiple estimations of possible fault locations.

Travelling wave methods are based on waves generated due to a fault event. When a fault occurs in the electrical grid an incident wave is emitted from the fault location and travels across the grid and reflects off the end of a line and therefore travels back up the line. The reflected waves also bounce off the fault location. A sensor can be used to record the arrival times of the waves on a line. This means that for a fault there is one incident wave and multiple reflection waves. The incident wave always arrives at a sensor before the reflection wave. A sensor does not cause a reflection. Traveling wave methods [1] include relay measurements and wavelet transformation. Relay measurements (e.g., [14]) are used to detect fault waves and calculate distances using a given propagation delay. Wavelet transform methods are similar to relay measurements but perform a wavelet transform on the signal to extract the surges(waves) and then distances are calculated using a given propagation delay (e.g., [15]).

Several solutions examine more sophisticated analysis of the travelling waves and add new components to improve accuracy of the localization results. These techniques employ neural networks and genetic algorithms [16,17,18].

Impedance based methods generate a distance from a sensor's location to the fault [3]. In a transmission grid there is only one power line being monitored and therefore only one location for the fault. A distribution grid however has multiple power lines branching away from the main power line. This results in the distance to the fault creating multiple locations along these branches rather than just one. FIG. 26 illustrate this possibility. FIG. 26 shows a distribution grid that uses a single sensor at point A. Assume a fault was calculated to be 950 meters away from the sensor. In this example, there are five possible fault locations (shown as black symbols in FIG. 26). As the number of branches and the area monitored increases the more possible fault locations there might be. Accordingly, implementation of impedance based methods in distribution grids presents a problem.

Travelling wave methods also generate a distance from a sensor. Since a transmission grid has one power line there is only one source for the reflected waves which is at the endpoint representing the end of the power line. In distribution grids however, there are many endpoints. The reflected waves detected can come from any of these endpoints. As a result, a valid endpoint location and reflected wave cannot be established.

The source endpoint of the reflected wave used to localize a fault must be known. If the sources of the reflected waves cannot be determined as is often the case in the distribution grid, then only a list of possible locations will be generated. This is done by using all combinations of reflected waves and endpoints. FIG. 27 shows the nine possible fault locations when the incident wave and just three reflected waves are recorded by the sensor with more than one endpoint. Only the list of possible locations can be determined because we do not know which endpoint caused which wave. All that can be done is to assume all reflected waves came from all endpoints. Existing methods focus on reducing the number of possible fault locations generated by these solutions in the distribution grid.

### Experimental Example 3.1: Fault Localization

Our approach uses multiple sensors and travelling waves to localize a fault. Rather than using the delay between incident wave and reflected wave recorded at one sensor, we use multiple sensors and we use the delay between the arrival times of the incident wave generated by a fault for each pair of sensors. In this subsection, we will describe the approach for a single line and in subsequent subsections we will discuss how our approach applies when there are branches.

If sensor i detects the incident wave at time ti and sensor j detects the incident wave at tⱼ, then delay(i,j) is calculated as tᵢ−tⱼ. The value of delay(i,j) represents the difference between the times that sensors i and j detect the fault signal. If delay(i,j) is zero then this indicates that the fault is in the middle of the power line. If delay(i,j) is positive then the location of the fault is between the midpoint and sensor j and if delay(i,j) is negative then the location is between sensor i and the midpoint of the power line. The delay value can be converted to a distance from the midpoint of the power line using the distance between i and j, and the speed, s, that fault signals traverses on the power line. Using this information, Equation 9 calculates the distance of the fault from sensor i. For a single line this is sufficient to determine the fault's location.

$$distance ( i ) = {d}_{i , j} + ( delay ( i , j ) * s ) / 2 \qquad ( Eq . 9 )$$

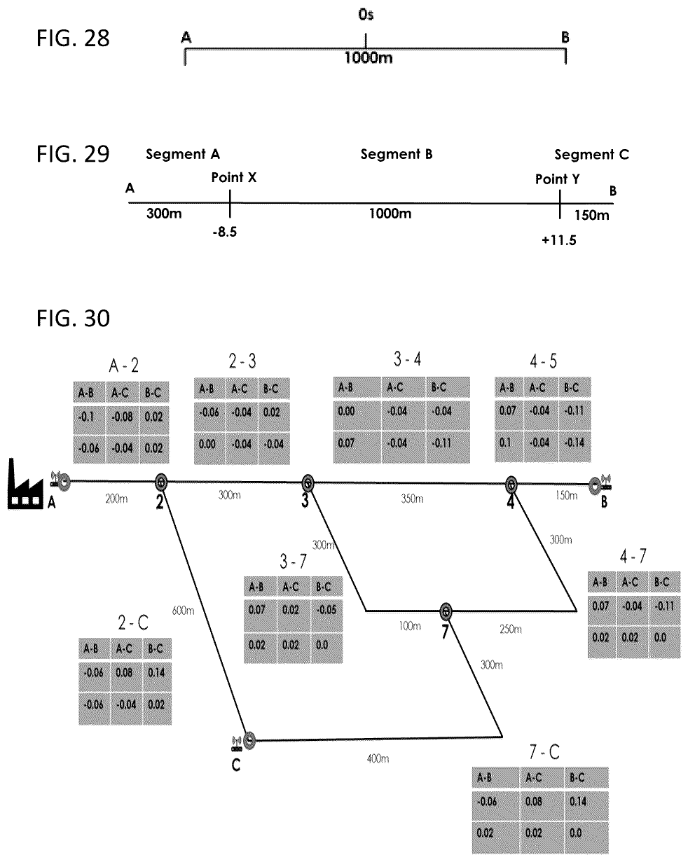

The distance from sensor j can be calculated by using delay(j,i) in Equation 9. FIG. 28 is used to demonstrate how Equation 9 can be used to calculate the distance of fault from a sensor for a single line.

FIG. 28 shows a power line of length 2000 m that uses a fault signal speed of 100 m/s. Sensors are placed at endpoints (represented by A and B) of the power line in FIG. 28. If the fault occurs at point A, the sensor at point B detects this 10 seconds after the sensor at point A. The delay is calculated as −10 and so the location is calculated to be at endpoint A. If the fault occurs at the midpoint then the delay is zero and hence the fault location is 500 meters from the sensor at point A.

With branching, it is possible for there to be multiple locations that are the same distance from a sensor. Segmentation is used to address challenges posed by branching.

The distribution grid can be conceptualized as a graph, G=(V,E). Each edge e∈E represents a segment of a power line. The set V represents the labels associated the vertices of the edges. Sensors are located at endpoints of power lines. Each edge e is associated with a set, W, of time windows. Each time window is a pair of values, (T_{i,j}^{l}(e), T_{i,j}^{u}(e)), that is associated with a pair of sensors, i and j, and represents the range of delays for a segment. The sensors are placed at endpoints of power lines. Given the number of sensors, n, the number of time windows per edge is n(n−1)/2. Segmentation is used to identify specific parts of the distribution grid to be examined to determine the fault location.

Time-windows can be applied to any segment of a power line. Assuming we have sensors, i and j, and edge (x,y), the amount of time before sensor i receives a fault signal that occurs at point x is dist(i,x)/s and for sensor j it is dist(j,x)/s and thus the lower and upper limits of the delay for sensors i and j is defined in Equation 10.

$${T}_{i , j}^{l} , {T}_{i , j}^{u} = \frac{dist ( i , x ) - dist ( j , x )}{s} , \frac{dist ( i , y ) - dist ( j , y )}{s} \qquad ( Eq . 10 )$$

FIG. 29 illustrates a concept of segmentation with two sensors placed at points A and B that represent the endpoints of a power line. It shows how a time-window for a segment of the line between point X and point Y is calculated. Using the distances in FIG. 29 and Equation 10, the lower and upper bounds of the time window for the segment between point X and point Y is calculated to be −8.5 and 11.5 respectively.

FIG. 30 illustrates how the use of time-windows and multiple sensors can be used to localize faults. We assume that the following information is available: the lengths of the power lines in the grid, the speed that the signal travels along the power lines, locations of the sensors used to detect the fault signal and locations of the edges.

FIG. 30 shows an example of a simple distribution grid that uses three sensors at the endpoints denoted by A,B and C. The grid is segmented into edges. Example edges include (A,2), (3,4), (3,7), (2,C). With three sensors there are three time-windows for each edge. In FIG. 30, each edge's time windows are presented in a table. Since there are three sensors, each table has three columns where each column represents the time window for each pair of sensors.

Algorithm 1 describes the approach used for identification of one or more edges that potentially could be where the fault is located. The input to Algorithm 1 (line 1) is the set of delays, represented by D and the set of time windows, W. For each edge, the value of delay(i,j) is compared to time windows associated with sensors i and j (line 5) to determine if there is a match. A match occurs if delay(i,j) is within the range represented by the lower and upper bounds of the time window. Edges in M represent possible segments that a fault may have occurred in.

ALGORITHM 1
Edge Match

| | |
|---|---|
| 1. | Input: D, W |
| 2. | Output: M |
| 3. | for each e ∈ E do |
| 4. | for each delay(i,j) ∈ D |
| 5. | if (T_{i,j}^{l} (e) ≤ delay(i,j) ≤ T_{i,j}^{u} (e) ) |
| 6. | M = M ∪ {e} |
| 7. | endif |
| 8. | endfor |
| 9. | endfor |
| 10. | return M |

Algorithm 2 is used to check if primary or secondary localization is to be applied. Primary localization is where a specific point can be determined as the location of the fault. Secondary localization occurs when potential segments are identified as potential locations for the fault but it is not possible to pinpoint the fault's location. Three cases may be considered.

Case 1: |M|=1 and T_{i,j}^{l}(e)≠T_{i,j}^{u}(e). This implies that there is exactly one edge that matches the fault key with a time window where upper and lower bounds are not equal. The exact location of the fault is then calculated using Equation 9. This case is classified as primary localization where an exact location has been determined.

Case 2: |M|=1 and T_{i,j}^{u}(e)=T_{i,j}^{u}(e): The edge has been identified but the upper and lower bounds are equal. This means that the distance cannot be calculated and an edge is highlighted as the location. This is classified as secondary localization. This case occurs if all points on the segment are the same distance from the sensors i and j. In this particular case there is only one segment that needs to be investigated.

Case 3: |M|>1: In this case there is more than one segment for which at least one pair of sensors have delay values that fall between the lower and upper bounds for the segment. This scenario is also classified as secondary localization since multiple edges are highlighted rather than a specific location. This case occurs if there are multiple segments where points on the segment are the same distance from the sensors i and j. This does not have to be all points but even a subset causes overlap of time windows.

For algorithm 2, the input is the values of delay(i,j), the distances between each pair of sensors, the fault signal speed s and the output of algorithm 1. Secondary localization is assumed to be the default (line 3). The set L is initialized to all edges in the set M (line 4). If M has more than one edge then L is returned (line 15) as secondary localization occurred. If M only has one edge (line 5) the algorithm checks if that edge has a time window where the lower and upper bounds are different (line 7). If this is the case then Equation 9 is used to calculate the location of the fault on that edge (line 8). The localization type is then changed to primary localization (line 9). These values are then returned (line 10). Otherwise, L is returned and the localizationType is secondary localization (line 12). If M has multiple edges then L is returned and the localization type is secondary (line 15).

ALGORITHM 2
Primary or Secondary Localization

| | |
|---|---|
| 1. | Input: delay, s, dist,M |
| 2. | Output: L, localizationType, D |
| 3. | localizationType = secondary |
| 4. | L = M; D=NULL |
| 5. | if ( size(M) = 1 ) |
| 6. | ∀e ∈ M |
| 7. | if (T_{i,j}^{l} (e) ≠ T_{i,j}^{u} (e)) |
| 8. | D = dist(i, j)/2 + (delay(i, j) * s)/2 |
| 9. | localizationType = primary |
| 10. | return D,localizationType |
| 11. | else |
| 12. | return L, localizationType |
| 13. | endif |
| 14. | else |
| 15. | return L, localizationType |
| 16. | endif |

Classifying edges as primary or secondary localization allows the identification of potential parts of the grid where the fault occurred.

The complexity of algorithm 1 depends on the number of sensor pairs which is n² (where n is the number of sensors) and the number of edges (segments), m, which is determined at deployment. The complexity of algorithm 2 is O(1). Although sensors are placed at endpoints, it is not necessarily the case that all endpoints need a sensor.

### Experimental Example 3.2: Evaluation

MATLAB was used to develop an electrical grid simulator using Simulink. A full electrical grid was simulated using Simulink electrical power components. In all tests a power generation component was used to simulate the generation of power of 120 Kv at 60 hertz which was then placed on the transmission lines. A substation component was then used to step down the 120 Kv power to 25 Kv typically found in distribution grids. Finally, several transformers and loads were added to the distribution area of the model to represent the final end-user power draw on the grid. Sensors are then added as required by the test cases and test configurations described below.

The distribution grid used for testing has 229 nodes and 243 edges. This graph is based on a map of a distribution grid in an Ontario town [2] that came with GPS locations of various points on the power lines. We used these points as nodes. The edges between these nodes were then used as segments. To evaluate the solution, 60 configurations of the test grid were used. Each configuration uses the same grid. The configurations differ in the number of sensors (between 2 and 50) and location of the sensors. These are randomly generated. For each configuration we randomly generated a fault location for each of the 243 edges which resulted in a corresponding fault signal. We then used our approach to localize the fault (243 times).

We then applied the following three tests on each configuration to evaluate the performance of the localization technique and edge classification: (1) Classify all edges as primary location edge (PLE) or secondary location edge (SLE) for each configuration and determine if the PLE and SLE classification was correct; (2) Determine the accuracy of the PLE faults to the meter; (3) Determine the accuracy of the SLE faults (if the set of edges returned contains the fault edge).

Table 2 shows a sample of 10 configurations taken from the 60 configurations used. For each configuration all edges in the graph were classified as PLE or SLE and then faults were placed on each edge at a random location as explained in the evaluation strategy. The fault was then localized to determine if it was on an edge classified as PLE or SLE. For all 60 configurations, a total 14,580 edges were classified with 60 different sets of random sensor locations with a random number of sensors (between 2 and 50), and all PLE and SLE classifications were correct.

TABLE 2
Result samples from PLE and SLE tests.

| | | Number of | | Number of | | |
|---|---|---|---|---|---|---|
| | Number | Classified | Actual | Classified | Actual | PLE/SLE |
| | of Sensors | PLE | PLE | SLE | SLE | Classification |
| Configuration | in Test | Edges | Edges | Edges | Edges | Accuracy |
| 1 | 29 | 23 | 23 | 220 | 220 | 100% |
| 2 | 23 | 56 | 56 | 187 | 187 | 100% |
| 3 | 24 | 41 | 41 | 202 | 202 | 100% |
| 4 | 17 | 40 | 40 | 203 | 203 | 100% |
| 5 | 31 | 35 | 35 | 208 | 208 | 100% |
| 6 | 7 | 30 | 30 | 213 | 213 | 100% |
| 7 | 20 | 59 | 59 | 184 | 184 | 100% |
| 8 | 31 | 41 | 41 | 202 | 202 | 100% |
| 9 | 9 | 34 | 34 | 209 | 209 | 100% |
| 10 | 17 | 20 | 20 | 223 | 223 | 100% |

Table 3 shows a subset of the tests from multiple configurations of the accuracy of the calculated fault location on the PLEs and SLEs. To test the accuracy of PLE localization, 200 of the 14,580 edges classified as PLE across the 60 grid configurations were then used to determine the exact fault location using our fault localization approach. The results shown in Table 3 are a sample of the 200 PLE accuracy tests. The error in meters was calculated as the difference between the actual location and the calculated location. The accuracy percent was calculated as the error divided by the length of the edge on which the fault was placed. The error on PLEs was a fraction of a meter. This held true for all 200 tests generating an average over 99%.

TABLE 3
Sample of localization accuracy for PLEs.

| | PLE Error | | |
|---|---|---|---|
| Test # | (in meters) | Length of Fault Edge | PLE Location Accuracy |
| 1 | 0.0097 | 561.80 | 99.999% |
| 2 | 0.0122 | 396.70 | 99.996% |
| 3 | 0.0075 | 122.60 | 99.992% |
| 4 | 0.0198 | 87.30 | 99.977% |
| 5 | 0.024 | 66.70 | 99.964% |
| 6 | 0.0204 | 67.90 | 99.970% |
| 7 | 0.3119 | 51.00 | 99.388% |
| 8 | 0.0151 | 41.00 | 99.970% |
| 9 | 0.0105 | 23.50 | 99.955% |
| 10 | 0.0195 | 18.60 | 99.895% |

SLE localization is the simpler of the two as it only requires the selection of the group of edges of which one edge contains the fault. The accuracy is based on whether the group of edges selected correctly encompassed the fault edge. Again 200 of the 14,580 edges classified as SLE edges were used across the 60 configurations. In all 200 SLE tests the algorithm correctly returned the fault edge within the group of edges returned generating an accuracy of about 100%.

Overall, both the primary and secondary edge classification tests and fault localization tests showed each method to be highly effective.

The solution presented in this experimental example allows highly accurate localization on all PLEs. Focus is now placed on when there are not an adequate number of sensors for full coverage of the grid, which results in SLEs (multiple fault locations). The solution presented by Jamie et al [19] also focuses on not having an adequate number of sensors. Without an adequate number of sensors multiple fault locations are returned. With their solution, Jamie et al [19] reduces the number of fault locations returned than previous methods in this scenario. The solution presented in this experimental example also addresses the scenario of inadequate monitoring and builds on this by allowing the user to see which areas of the grid will return multiple locations if a fault were to occur in those areas.

Our work provides an approach to fault localization in a distribution grid based on multiple sensors, segmentation and the use of delays representing when sensors receive the incident wave caused by a fault. This enables us to localize the fault when there are many possible locations for the fault. Our evaluations show that the approach has huge potential based on results that show that the fault localization solution can very accurately localize faults on a distribution grid.

Our results suggest that the total number of PLEs is not correlated with the number of sensors used. In the results shown in table 1, the total number of PLEs in in each configuration did not appear to be correlated with the number of sensors used. For example, taking configurations 1 and 2 as examples, this is apparent. In configuration 1 it is seen that 29 sensors only resulted in 23 PLEs. On the other hand, configuration 7 only used 20 sensors but generated 59 PLEs. The placement of sensors was random. This suggests that the effectiveness of our approach depends on the location of the sensors in the grid.

Generally, for fault localization to occur the grid must be energized. A few seconds after a fault occurs, the grid is powered down and is no longer active. It is possible that there can be multiple areas of a distribution power line being damaged. However, due to the speed of the fault signals, it is improbable that the faults causing the damaged areas would occur while the grid is still energized. Therefore, in scenarios with multiple damaged areas solutions that localize faults like the one presented in this paper do so for the first fault which is the fault that causes the power outage to occur. If there is another fault then after fixing the first fault, the other fault will stop the distribution grid. The process of fault localization is repeated.

### Reference List for Experimental Example 3

1 Marguet, R.: ‘Improved fault localization method for electrical power distribution networks’, 2015
2 Ontario Electricity Provider, 2018
3 Andrade, L. d., and Leão, T. P. d.: ‘Impedance-based fault location analysis for transmission lines’, in Editor (Ed.)\hat{ }(Eds.): ‘Book Impedance-based fault location analysis for transmission lines’ (2012, edn.), pp. 1-6
4 Saha, M., Provoost, F., and Rosolowski, E.: ‘Fault location method for MV cable network’, 2001
5 Das, S., Kulkarni, S., Karnik, N., and Santoso, S.: ‘Distribution fault location using short-circuit fault current profile approach’, in Editor (Ed.)\hat{ }(Eds.): ‘Book Distribution fault location using short-circuit fault current profile approach’ (2011, edn.), pp. 1-7
6 Karnik, N., Das, S., Kulkarni, S., and Santoso, S.: ‘Effect of load current on fault location estimates of impedance-based methods’, in Editor (Ed.)\hat{ }(Eds.): ‘Book Effect of load current on fault location estimates of impedance-based methods’ (2011, edn.), pp. 1-6
7 Qin, J., Chen, X., and Zheng, J.: ‘Travelling wave fault location of transmission line using wavelet transform’, in Editor (Ed.)\hat{ }(Eds.): ‘Book Travelling wave fault location of transmission line using wavelet transform’ (1998, edn.), pp. 533-537 vol. 531
8 Girgis, A. A., Fallon, C. M., and Lubkeman, D. L.: ‘A fault location technique for rural distribution feeders’, IEEE Transactions on Industry Applications, 1993, 29, (6), pp. 1170-1175
9 Jun, Z., Lubkeman, D. L., and Girgis, A. A.: ‘Automated fault location and diagnosis on electric power distribution feeders’, IEEE Transactions on Power Delivery, 1997, 12, (2), pp. 801-809
10 Seung-Jae, L., Myeon-Song, C., Sang-Hee, K., Bo-Gun, J., Duck-Su, L., Bok-Shin, A., Nam-Seon, Y., Ho-Yong, K., and Sang-Bong, W.: ‘An intelligent and efficient fault location and diagnosis scheme for radial distribution systems’, IEEE Transactions on Power Delivery, 2004, 19, (2), pp. 524-532
11 Gabr, M. A., Ibrahim, D. K., Ahmed, E. S., and Gilany, M. I.: ‘A new impedance-based fault location scheme for overhead unbalanced radial distribution networks’, Electric Power Systems Research, 2017, 142, pp. 153-162
12 Estebsari, A., Pons, E., Bompard, E., Bahmanyar, A., and Jamali, S.: ‘An improved fault location method for distribution networks exploiting emerging LV smart meters’, in Editor (Ed.)\hat{ }(Eds.): ‘Book An improved fault location method for distribution networks exploiting emerging LV smart meters’ (2016, edn.), pp. 1-6
13 Mwifunyi, R. J., Kissaka, M. M., and Mvungi, N. H.: ‘Distributed approach in fault localisation and service restoration: State-of-the-Art and future direction’, Cogent Engineering, 2019, 6, (1), pp. 1628424
14 Crossley, P. A., and McLaren, P. G.: ‘Distance Protection Based on Travelling Waves’, IEEE Transactions on Power Apparatus and Systems, 1983, PAS-102, (9), pp. 2971-2983
15 Magnago, F. H., and Abur, A.: ‘Fault location using wavelets’, IEEE Transactions on Power Delivery, 1998, 13, (4), pp. 1475-1480
16 Pourahmadi-Nakhli, M., and Safavi, A. A.: ‘Path Characteristic Frequency-Based Fault Locating in Radial Distribution Systems Using Wavelets and Neural Networks’, IEEE Transactions on Power Delivery, 2011, 26, (2), pp. 772-781
17 Wen, F., and Chang, C. S.: ‘A new approach to fault diagnosis in electrical distribution networks using a genetic algorithm’, Artificial Intelligence in Engineering, 1998, 12, pp. 69-80
18 Srinivasan, D., Cheu, R. L., Poh, Y. P., Kim, A., and Ng, C.: ‘Automated fault detection in power distribution networks using a hybrid fuzzy±genetic algorithm approach’, 2000
19 Jamei, M., Ramakrishna, R., Tesfay, T., Gentz, R., Roberts, C., Scaglione, A., and Peisert, S.: ‘Phasor measurement units optimal placement and performance limits for fault localization’, IEEE Journal on Selected Areas in Communications, 2019, 38, (1), pp. 180-192

### Experimental Example 4

This experimental example provide solutions to optimize the placement and number of sensor devices used in the fault localization system. Two contrasting approaches are discussed and compared to determine an effective method of optimizing the placement of sensors in a problem that scales well. The first method is a greedy algorithm that restricts the possible solutions evaluated and significantly reduces the computational cost, and the second is a genetic algorithm that eases those restrictions at an increased computational cost.

The fault localization solution exemplified and validated in Experimental Example 3 can be summarized as follows:
Segmenting the electrical grid
Establishing time-windows for each segment
Upon the occurrence of a fault identify the faulty segment using the time windows
Calculate fault location on the faulty segment.

To determine the location of a fault, the delay between that fault's arrival time to each sensor/device (referred to as the fault key) is compared to each of the time windows of each segment/edge (referred to as the edge key) to find a match. A match occurs once the fault key falls within the one of the time-windows of an edge key. The match would indicate which edge of the cable the fault occurred.

After identifying the faulty segment of the cable, the fault location on the identified faulty segment can then be determined. However, there are cases in which either the correct segment cannot be identified or the fault location on an identified faulty segment cannot be determined. As described in Experimental Example 3, two types of localization, primary and secondary localization, address these cases.

Primary localization occurs when only one segment matches the fault key and one of the time-windows of that segment is valid. When one segment matches the fault key, that segment can be identified as the fault segment. After this a valid time window is used to determine the fault location on the identified fault segment. A valid time window has a different lower and upper bound. If more than one segment matches the fault key or there is no valid time window, only a fault area can be determined. This is referred to as secondary localization.

There are three cases that may occur during the localization process:
Case 1 (Primary Localization)—A single segment matches the fault key with a valid time-window.
Case 2 (Secondary Localization)—A single segment matches the fault key and there is no valid time window
Case 3 (Secondary Localization)—Multiple segments match the fault key.

Using these three cases, each segment can be classified as a primary or secondary localization segment. Each segment can be classified by determining if one of a segment's time windows is unique and if there is a valid time window.

Segment classification is dependent on the number and location of the sensors (referred to as sensor configuration). The link between segment classification and a given sensor configuration provides a way of evaluating the performance of a sensor configuration. The classification of the segments can be used to determine which parts of the electrical grid are covered by either primary or secondary localization. The classification of segments shows how well faults can be localized with a given number and location of sensors.

Primary segment classification can establish a metric that correlates to the effectiveness of the placement of the sensors. The amount of power cable in the grid (in meters) that is classified under primary localization segments is used as the performance metric. This metric can then be used to compare the performance of different sensor quantities and locations. We use this to optimize the number and location of sensors, reducing the cost of localizing faults.

In this Experimental Example 4 the optimization of sensor placement problem is defined as a subset problem [Qian et al. 2017]. The size of the problem's search space is also shown to provide perspective of the work to be done to find an optimal solution. In addition to this, a definition of the objective function used to determine a solution's performance (towards the optimization goal) is also provided. This function is used by both optimization methods explored to provide a consistent metric for the performance of solutions generated by the optimization methods.

Given an undirected graph G=(V, E), each vertex/node v E V is a possible location for a sensor in the grid and each edge e∈E is the electrical cable between each adjacent node (possible sensor location).

Each node in a graph is numbered and is an element in the set V and the edges E are the paths (electrical cable) that exist between those nodes.

Let the set T contain the time windows (given as the upper bound T_{i,j}^{u} and lower bound T_{i,j}^{l}) for all pairs i, j of V, for each edge e∈E. An edge e∈E qualifies as a primary localization edge if it meets the following criteria:
When the edge e is compared to each other edge there exists at least one unique time window (T_{i,j}^{l}(e), T_{i,j}^{u}(e)) in every comparison that does not overlap (the edge is uniquely identifiable).
For that edge e there is a time window where the upper and lower bounds are not the same (there is a valid time window).
   The primary localization criteria can be formulated as follows:
∃T_{i,j}^{l}(e)∈T(lower bound) and T_{i,j}^{u}(e)∈T(upper bound) such that ∀k∈E, k≠e and [symbol] T_{i,j}^{l}T(e)≤T_{i,j}^{l}(k)≤T_{i,j}^{u}(e) and T_{i,j}^{l}(e)≤T_{i,j}^{u}(k)≤T_{i,j}^{u}(e)
T_{i,j}^{l}(e)≠T_{i,j}^{u}(e).

The optimal sensor placement problem can be formulated as an optimization problem in which one aims to maximize (or minimize) a user-defined objective function related to the characteristics of a structural system, where the sensor locations are defined as the discrete optimization variables (parameters) subject to a constraint. It is important to note that the constraint used by the optimization problem may be redefined by industry. As the constraint is unknown, a reasonable assumption is made to define the constraint which is that there will be a maximum number of sensors to be placed in the grid. For the testing performed in this chapter the constraint used is a maximum number of sensors. However, industry may have a different view or views on what acceptable solution may be. To account for this variability, the formulation of the optimization problem is kept as general as possible.

In this experimental example, sensor placement is a finite subset of locations S from V where V represents all possible locations for placing sensors in the distribution grid. The goal is to maximize the amount of cable classified as a primary localization edge (PLE). The problem can be formulated as follows:

$$max {\sum }_{i = 1}^{n} f ( S , i ) * w ( i ) subject to Cost ( S ) < B \qquad ( Eq . 11 )$$

Where n is the number of edges and f(S, i) returns 1 if the edge i is a PLE and 0 if it is not. w(i) returns the weight of the edge i. B represents the budget, and the cost function Cost(S) evaluates the cost of the sensors used in relation to the budget B. Essentially, the problem is to select a subset, S, of V that maximizes the objective function. The constraint on the choice of S is that the cost of the selection made (given by cost of S) be less than some threshold (budget) B. Multiplying the return value of f by the weight of the edge allows the total amount of cable that satisfies the primary localization criteria to be calculated. This weight allows not just the length of the cables to be considered but can also allow priorities (in monitoring certain areas of the grid) to be incorporated if needed.

This is a finite combinatorial optimization problem, so one way to solve it is by brute force. This requires enumerating all possible subsets where cost(S) is within the budget, evaluating f, and picking the best subset. The number of possible subsets is very large. The number of possible subsets grows extremely fast as V increases, so the brute force approach quickly becomes infeasible as V becomes large. The problem in our work is considered to be a subset problem which is NP complete [Hamo and Markovitch 2005].

The greedy algorithm and genetic algorithm approaches are now described.

Greedy Algorithm. Greedy algorithms often only find locally optimal solutions, but can provide decent approximations to problems [Cormen et al. 2009]. A detailed explanation on greedy algorithms is provided by [Cormen et al. 2009] who argue that in many cases greedy algorithms are able to find the globally optimal solution. There are several types of greedy algorithms stated by [Lin et al. 2013] who also note four of the most commonly used types of greedy algorithms are:
Pure greedy
Relax greedy
Orthogonal
Stepwise projection

An in depth technical look at these main types of greedy algorithms are provided in [Dereventsov 2012][DeVore and Temlyakov 1996][Temlyakov 2003][Barron et al. 2008]. The efficiency of these methods are discussed by [Temlyakov 2003] as it relates to approximation and outlines some variations of these methods.

Genetic Algorithm. Optimization techniques are categorized as being calculus-based, enumerative or guided random [Bandyopadhyay and Saha 2013]. We pay particular attention to guided random techniques and specifically genetic algorithms due to their ability to handle problems where the search space is large and near optimal solutions are acceptable, which is the case for our optimization problem. We can use genetic algorithms as the placement of sensors is a combinatorial optimization problem. A genetic algorithm (GA) is an iterative, reinforcement learning, guided search technique that explores a search space, based on survival of the fittest to find optimal or near optimal solutions to combinatorial optimization problems. A concise survey of GAs is conducted by [Srinivas and Patnaik 1994]. A large source of information on GAs is provided in [Ghosh and Dehuri 2004] that shows the considerations one has to make when employing GAs.

GAs are a very effective means of finding optimal or near-optimal solutions to combinatorial optimization problems [Bandyopadhyay and Saha 2013]. They intelligently navigate through the possible solutions of a given problem in search of an optimal solution [Bandyopadhyay and Saha 2013]. GAs encode an optimization solution into a chromosome. A chromosome is a representation of a solution in a form (like a string of integers) that allows it to be easily manipulated by the following genetic operations:
Initialization—Creating an initial random set of solutions (chromosomes) called a population.
Fitness Evaluation (performance)—Determines how well a solution performs against the defined objectives.
Selection—This refers to solutions (chromosomes) used to generate the new population (based on fitness).
Crossover—This is the process by mixing parts (genes) of chromosomes to generate a new chromosome.
Mutation—This introduces random parts (genes) to maintain a diverse gene pool.

Algorithm 3 shows how these operations are used in a genetic algorithm during its execution.

ALGORITHM 3
Basic GA

| | |
|---|---|
| 1. | Create E (initially nil) for elite performers |
| 2. | Initialize population set P |
| 3. | While termination criterion not met do |
| 4. | Evaluate(P) |
| 5. | Update E with best performers in P and E |
| 6. | Set X = Selected solutions from E |
| 7. | Set P = Crossover and Mutated set X |
| 8. | Endwhile |

Line 1 creates an empty set for elite performers. The elite performers are the best performing solutions found by the algorithm. Line 2 initializes the population with randomly generated solutions which are usually random integers. The rest of the algorithm (lines 4 to 7) executes a loop until the criteria for termination (e.g., number of iterations; a certain fitness threshold) is met. In this loop the population (set of solutions) is evaluated to determine how well they have performed in relation to the optimization goal (line 4). E is updated to hold the best performing solutions (line 5). The elite solutions are then selected to generate a new population via the crossover operation (line 6). A new generation of solutions created by the crossover and mutation operations replaces the solutions in P (line 7). Once the loop ends the best performing solutions found during the algorithm's execution would be found in E. The best performing solution in E is selected as the final solution.

The greedy based approach is evaluated in [Vafaie and Imam 1994] against a genetic algorithm approach for feature selection (determining which features should be used from a set of data for making decisions about that data). They found that when it comes to feature selection, greedy-like searches get trapped in local peaks but can be more efficient in some cases. The work presented in [Vafaie and Imam 1994] also found that the GA-based method was able to improve the robustness of the feature selection at the expense of increased computational complexity. The work in this experimental example further explores the performance of greedy and genetic algorithms in a different problem. We specifically compare the two in optimizing sensor locations for the solution developed in [Hunte et al. 2021] with the end goal being the selection of a cost efficient optimization algorithm to reduce the resources needed by the fault localization solution. The optimization problem can be defined as a maximization of the number of PLEs generated by a set of sensor locations as a subset of the total nodes in the graph.

To find optimal or near optimal solutions the need to compare solutions is necessary. We now present an evaluation function that allows a score to be provided for a given solution. This function can be used by both the greedy and genetic algorithms to compare the quality of different solutions. For this evaluation function, a possible solution to the optimization problem is given as a set S of nodes (sensor locations) where S⊆V and V is the set of all nodes in the electrical grid's graph. The set S is of size n, with n representing the number of sensors to be placed in the grid. The set S is used to generate the set TW of time windows for each pair of sensors for each edge as discussed in [Hunte et al. 2021]. The total PLE coverage (sum of the cable lengths of the primary localization edges) is used as the score for the set S for the evaluation function and tests performed in this chapter. The sum of the cable lengths is used as the score for a solution because each edge may have a different length. If the lengths of cables are not considered, then an edge representing a 10 km cable and an edge representing a 1 km cable will be treated the same (each having a value of 1) by the optimization algorithm. The optimization algorithm would then be unable to distinguish between a solution where the 1 km cable is covered under primary localization and the 10 km cable is covered. In reality, the solution covering the 10 km cable is the better option. To avoid this, the lengths of cables are considered in the score for the solutions by adding weights to each edge which is the length of cable for that edge in the electrical grid. A solution's score is then calculated by adding the weights of the PLEs in the graph.

ALGORITHM 4
Evaluate

| | |
|---|---|
| 1. | Input: S. V. E //set of sensor locations S and vertices V and edges E |
| 2. | Output: total_PLE //total cable classified as primary localization |
| 3. | numEdges = size ( E ) |
| 4. | TW[ ][ ] // 2-D array of edge objects to hold the set of time windows for each |
| 5. | TW = generate TimeWindows( S, V, E ) //create a set of time windows for each |
| 6. | Set total_PLE to 0 and edgeCount to 0 |
| 7. | for i = 0 to numEdges do //select an edge i to see if it is uniquely identifiable |
| 8. | edgeCount = 0 |
| 9. | for j = 0 to numEdges do //iterate through all other edges j |
| 10. | if (i != j) //do not compare the time windows for the same edge |
| 11. | for m = 0 to size( timeWindow ) do //iterate through all time windows |
| 12. | //check to see if the time window does not have an overlap |
| 13. | if (TW[j][m].lower > TW[i][m].upper) OR (TW[j][m].upper < |
| 14. | edgeCount = edgeCount + 1 // a unique time window has been |
| 15. | break //no need to continue checking other time windows |
| 16. | endif |
| 17. | endif |
| 18. | if ( TW[i][m].upper != TW[i][m].lower ) //check if there is a valid |
| 19. | validTWExists = true //a valid time window exists for edge i |
| 20. | endif |
| 21. | endfor |
| 22. | endif |
| 23. | endfor |
| 24. | if (edgeCount == numEdges) //the edge i is uniquely identifiable |
| 25. | if( |
| 26. | total_PLE = total_PLE + length(E[i]) |
| 27. | endif |
| 28. | endfor |
| 29. | return total_PLE |

Each edge represents a segment of a power line and is associated with a set of time windows for each pair of sensors. Algorithm 4 (the Evaluate function) takes as input a set S of sensor locations and the vertices and edges that represent the grid (line 1). The Evaluate function returns the total amount of cable classified as primary localization. The algorithm generates a set of time windows (TW in line 5). The variable TW holds the time windows (T_{i,j}^{l}(e), T_{i,j}^{u}(e)) for each pair of sensors i, j for each edge e∈E. Here, the first dimension of TW is used to access the edge and the second dimension is used to access a single time window within that edge. The outer for loop (line 7) goes through each edge to check if edge i has a time window with no overlap. The second for loop starting on (line 9) allows the current edge i to be checked against all other edges. The third for loop iterates through each time window for the edges being compared (line 11) to look for a unique time window. Inside the third loop is an if statement (lines 13 to 16) which increments edgeCounter if a unique time window is found for edge i. An edge e∈E qualifies as a primary localization edge if it meets the following criteria:
When the edge e is compared to each other edge there exists at least one unique time window (T_{i,j}^{l}(e), T_{i,j}^{u}(e)) in every comparison that does not overlap (the edge is uniquely identifiable).
For that edge e there is a time window where the upper and lower bounds are not the same (there is a valid time window).

If a unique time window is found for edge i for each other edge, then edge i satisfies the first criteria for primary localization (being uniquely identifiable). If the variable validTWExists is true, then the second and final criteria for primary localization (having a valid time window) is also true and the edge i would be a PLE. As such the length of edge i is added to total_PLE. At the end of the Evaluate function the variable total_PLE contains the total length of all PLEs. This evaluation function is used in Section 5.5 in a greedy algorithm and in Section 5.6 in a genetic algorithm to determine the performance of a given solution. In our evaluation function we use the weight of each edge to convert the number of PLEs to a total amount of cable to account for edges/segments being of different lengths rather than just a count of the number of PLEs.

### Experimental Example 4.1: A Greedy Algorithm for Optimization of Senor Locations

The greedy algorithm presented in this experimental example takes an incremental approach to optimizing sensor locations (adding one sensor at a time). However, the requirement for the problem is that there must be no less than two sensors. The origin of this is in the fact that the localization technique in [Hunte et al. 2021] requires at least two sensors. Therefore, the placement of two sensors must be done first and then the general greedy algorithm can be executed to add additional sensors until the desired n sensors are placed. The greedy algorithm is shown in Algorithm 5.

The greedy algorithm takes as input the number of sensors to be placed in the grid and the nodes in the graph (potential sensor locations) (line 1). It then calculates the locations for the initial two sensors by using an exhaustive search of all possible pairs of nodes to find the globally optimal locations for the first two sensors (maximizing the amount of cable classified as being PLEs) (line 4) and removes these first two nodes from the list of potential locations in Nodes. The algorithm then enters a series of loops. The inner loop takes the set of sensor nodes and searches through all remaining potential sensor locations in the nodes variable to determine the next sensor's best location (lines 7 to 14). The outer loop repeats the addition of a sensor location until the desired number of sensors have been placed (line 5).

ALGORITHM 5
Greedy

| | |
|---|---|
| 1. | Input: numberOfSensors, Nodes |
| 2. | Output: locations |
| 3. | locations = [ ] |
| 4. | [locations Nodes] = initialSensorPair(Nodes) //generate first 2 |
| | locations |
| 5. | for j=1: numberOfSensors - 2 do //choose the remaining n-2 sensor |
| | locations |
| 6. | bestPerformance = 0 |
| 7. | for i=1:numberOfLocations do //find the next best sensor location |
| 8. | sensorNodes = [locations Nodes[i] ] //add the ith location for |
| | evaluation |
| 9. | performance = Evaluate( sensorNodes ) //check performance of the |
| | ith location |
| 10. | if ( performance > bestPerformance )//update the current best |
| | location if needed |
| 11. | bestLocation = Nodes[i] |
| 12. | bestPerformance = performance |
| 13. | endif |
| 14. | endfor |
| 15. | locations = [locations bestLocation] //add the nest best location |
| | found to the list |
| 16. | endfor |
| 17. | return locations //return final set of sensor locations |

### Experimental Example 4.2: A Genetic Algorithm for Optimization of Senor Locations

The use of the genetic algorithm is to provide the necessary flexibility to allow the initial sensor locations to be changed. This allows a greater number of solutions in the search space to be explored. The genetic algorithm used for the optimization of sensor locations for n sensors is outlined in Algorithm 6. It uses traditional genetic operations to navigate the search space and find optimal or near optimal solutions.

Algorithm 6 shows the operations performed by the genetic algorithm. In this section an explanation of the algorithm's design is provided. In this explanation the term random is used to refer to the use of a random number generator.

The genetic algorithm takes the number of sensors to be placed in the grid as input. Next E is initialized to hold the ten best performing solutions found (line 3). The size of the elite set was tested with values from 1 up to 100 (the size of the population) in increments of ten. An elite set size of 10 was chosen as it is the smallest size that consistently provided optimal or near optimal solutions.

On line 4, the variable max is set to fifty so that the while loop runs until there has been no change to E for fifty generations. This was chosen because the genetic algorithm uses a dynamic probability of mutation (pm) when convergence is detected. The probability of mutation is adjusted according to the rate of convergence similarly to the method presented in [Srinivas and Patnaik 1994]. Convergence occurs in this scenario when there is no change in the elite set. The genetic algorithm presented starts with a mutation rate of 0.02 and when convergence is detected the mutation rate is increased by 0.02 up to the maximum value of one. This would require fifty iterations to increase the mutation rate to its maximum value.

ALGORITHM 6
Genetic

| | |
|---|---|
| 1. | Input: numberOfSensors, numberOfNodes, Nodes |
| 2. | Output: locations |
| 3. | E = null //2D array to hold elite chromosomes |
| 4. | convergeCounter = 0, max = 50, pSize = 100 |
| 5. | P = initialize( numberOfSensors , pSize ) //create initial population |
| 6. | while convergeCounter < max do //execute until the algorithm has |
| 7. | for i = 1:size(P) do //evaluate each chromosome (solution) |
| 8. | performance(i) = Evaluate( P(i) ) //function as defined in section 5.4 |
| 9. | endfor |
| 10. | prevE = E //temporarily store old elite set to check for change |
| 11. | E = update(performance, E, P) //update E with best solutions in |
| 12. | if ( prevE = E ) //check for a change in elite set (detect convergence) |
| 13. | convergeCounter = convergeCounter + 1 |
| 14. | else |
| 15. | convergeCounter = 0 //reset counter whenever a change is detected |
| 16. | endif |
| 17. | X = select(E, P, numberOfSensors) //choose chromosomes for |
| 18. | P=crossoverAndMutate(X, convergeCounter, numberOfSensors, |
| 19. | endwhile |
| 20. | return locations = max( E ) //return best solution |

The population size was set to 100 (line 4) as it is considered a reasonable small population size by [Srinivas and Patnaik 1994] and as such would use a smaller amount of resources than larger population sizes, maintaining a focus on the efficiency of the optimization process. The population P is therefore initialized with a set of 100 chromosomes (line 5).

The while loop (lines 6 to 19) allows:
The solutions in P (the current generation) to be evaluated (line 7 to 9)
The elite set E to be updated with the ten best solutions (line 11)
The solutions in E and P to be selected for crossover for creating the next generation of solutions (line 17)
The genetic operators (crossover and mutation) to be performed to create new generations (line 18)

Once the loop terminates the best solution in the elite set is selected as the final solution.

Selection is performed (on line 17) by choosing random chromosomes (by using a random integer generator to generate the indices of the chromosomes) from the elite set E and members of the current population P to create the set chromosomes needed for the crossover operation (creating the next generation). The crossover probability (pc) was set to one for each iteration. Setting pc to one ensures that all members of the next generation will be a result of the crossover operation. The maximum value of one was used for the crossover probability as it is a common value used when implementing genetic algorithms [Srinivas and Patnaik 1994].

The crossoverAndMutate function (line 18) creates the next generation of solutions from the set returned by the select algorithm. The number of chromosomes to be mutated is controlled by the value of pm. The value of pm is used as a percentage of the population size to determine the number of new chromosomes that will be mutated. The initial value of pm would be 0.02 until convergence is detected. When convergence is detected (no change in the elite set) the initial value of 0.02 would be multiplied by convergeCounter (passed into the crossover and mutate function on line 18) to provide the value of pm.

If the new chromosome is to be mutated, each of the genes are chosen randomly (by using a random integer generator) from all possible values for a gene (any node) as long as it does not create a duplicate gene in the chromosome. If it is not a mutated chromosome then two random chromosomes (by using a random integer generator to generate the indices of the chromosomes) are chosen from X (as a pair of parents). A new chromosome is created from the genes of that pair unless it is selected for mutation.

An example of the genetic algorithm's chromosomes is presented in Table 4 to explain chromosomes and genes of the genetic algorithm. Each chromosome will have n genes, each representing one of the n sensors to be placed in the distribution grid. The integer value stored in each of the n genes represents the node identifier number in the graph where that sensor is to be located. Table 4 shows an example population of four chromosomes and for optimizing the placement of 5 sensors. In this scenario E will hold the top 2 performing solutions. The fitness value column in Table 4 shows the amount of electrical cable of the grid that is categorized as PLE.

In this case chromosomes 2 and 4 would be placed in the elite set as placing sensors on the nodes in their chromosomes would result in the most PLE coverage (50 Km and 42 Km respectively). The selection process randomly chooses chromosomes from the elite set E and the population P (by using a random integer generator to generate the indices of the chromosomes) for the crossoverAndMutate function.

The crossoverAndMutate function creates a pair (parents) from the selected chromosomes in X. Each pair's genes (which are nodes selected as sensor locations) are used to generate a new chromosome. The number of chromosomes to be mutated is controlled by the value of pm. The value of pm is used as a percentage of the population size to determine the number of new chromosomes that will be mutated. If a new chromosome is to be mutated, then it is created by selecting random genes (by using a random integer generator) from all possible node locations.

TABLE 4
An example population for the optimization problem.

| | | | | | | Fitness | |
|---|---|---|---|---|---|---|---|
| | | | | | | Value | |
| | | | | | | (PLE | |
| Solution | Gene 1 | Gene 2 | Gene 3 | Gene 4 | Gene 5 | Coverage) | |
| 1 | 215 | 79 | 139 | 107 | 7 | 16 | Km |
| 2 | 33 | 220 | 214 | 90 | 8 | 50 | Km |
| 3 | 10 | 174 | 40 | 109 | 9 | 6 | Km |
| 4 | 218 | 176 | 103 | 64 | 28 | 42 | Km |

After the mutations have been made a new generation of solutions would have been created. This population of new chromosomes would go through the same process of updating the elite set and creating new populations until j=50 and the algorithm terminates. If a change in the elite set is detected j will be reset to 0 and the mutation rate would be reset to 0.02. When the while loop terminates the best solution in the elite set is then selected as the final solution.

There are five functions used in the genetic algorithm:
1. Initialize
2. Evaluate
3. Update
4. Select
5. CrossoverAndMutate

The initialize function uses the number of sensors as the number of genes in the chromosomes and uses pSize as the number of chromosomes in the population. This function uses a random integer generator to create each chromosome's genes. The random generator is given the number of nodes available for sensor locations. Each node in the grid is identified by an integer from 1 (the first node) up to numberOfNodes (the last node).

ALGORITHM 7
Initialize

| | |
|---|---|
| 1. | Input: numberOfSensors, pSize |
| 2. | Output: P //Initial population |
| 3. | P = new Array( pSize ,numberOfSensors) |
| 4. | for j=1: pSize do //generate each chromosome for the population |
| 5. | for i=1: numberOfSensors do //generate each chromosome's genes |
| | randomly |
| 6. | P[i][j] = randi ( 1, numberOfNodes ) //random integer generator |
| 7. | endfor |
| 8. | endfor |
| 9. | return P |

The evaluation function used in the genetic algorithm is Algorithm 4 (Evaluate). The update function is defined in the Update algorithm (Algorithm 8). The Update function maintains the elite set by updating it with any new high performing chromosomes (solutions). The update algorithm adds the elite set to the population and then sorts all chromosomes in descending order. The update function then takes the top ten solutions and overwrites the elite set with the best ten solutions.

ALGORITHM 8
Update

| | |
|---|---|
| 1. | Input: performance, E, P |
| 2. | Output: E //Updated elite set |
| 3. | allSolutions = append ( P, E) //combine both elite solutions and |
| | population |
| 4. | Sort(allSolutions, performance) //sort using performance of each |
| | solution |
| 5. | for i=1: 10 do //only select top ten as elite set size is 10 |
| 6. | E[i][:] = allSolutions [i][:] |
| 7. | endfor |
| 8. | return E |

The select function is shown in the Select algorithm (Algorithm 9). The select function takes the elite set E and the population P. A random integer generator is used to generate indices for choosing the solutions from the elite set E and then the population P that will be used in the crossover operation. The selected chromosomes from both E and P are placed in X.

ALGORITHM 9
Select

| | |
|---|---|
| 1. | Input: E, P, numberOfSensors |
| 2. | Output: X //Set of chromosomes for crossover |
| 3. | for j=1: numberOfSensors do //select solutions from elite set |
| | randomly |
| 4. | index = randi( 1, size( E) ) |
| | elite= E[index][:] |
| 5. | endfor |
| 6. | for i=1: numberOfSensors do //select solutions from |
| | population randomly |
| 7. | index = randi( 1, size( P ) ) //random integer generator |
| 8. | population = P[index][:] |
| 9. | endfor |
| 10. | X = append(elite, population ) //combine selected solutions |
| | for crossover |
| 11. | return X |

The CrossoverAndMutate function (Algorithm 10) takes the set X selected for crossover and mutation. It first calculates the value of pm (line 4) according to the rate of convergence. The mutateCount counter (line 5) ensures that the correct number of chromosomes are mutated according to the value of pm. The CrossoverAndMutate function then enters a loop (line 6 to 17) that creates enough chromosomes for a new population Two chromosomes are chosen from set X (line 7 and 8) as two parents are needed for each new member. The genes of both parents are then stored in genePool (line 9). Another for loop is then executed to create each gene for the new chromosome (line 10 to 16). If the chromosome is to be mutated (we have not mutated enough chromosomes yet), the genes are chosen randomly from all possible values which is any node in the grid (line 12). The randi function generates a random integer between the two parameters passed to the function. The uniqueRandi function takes the current chromosomes genes and the range of integers to generate. It generates a random integer that is not already in the chromosome, ensuring that the genes added to the chromosome are not repeated. If all of the mutated chromosomes have been created (line 11), then the genes are selected from the parent's genes in genePool (line 14). After creating all the new chromosomes, the new population is returned (line 18).

ALGORITHM 10
CrossoverAndMutate

| | |
|---|---|
| 1. | Input: X, numberOfSensors, numberOfNodes , convergeCounter, |
| | pSize |
| 2. | Output: P //new population |
| 3. | P = null |
| 4. | pm = (convergeCounter * 0.02) //dynamically set pm based on |
| | convergence |
| 5. | mutateCount = pm * pSize //used mutate a percentage of the new |
| | chromosomes |
| 6. | for i=1: pSize do //create new chromosomes for new population |
| 7. | parentA= X[ randi( 1, numberOfSensors) ][:] //select 1^{st} parent at |
| | random |
| 8. | parentB = X[ randi( 1, numberOfSensors) ][:] //select 2^{nd} parent at |
| | random |
| 9. | genePool = merge( parentA , parentB ) //collect genes and remove |
| | duplicates |
| 10. | for j=1: numberOfSensorsdo //create each gene for each new |
| | chromosome |
| 11. | if (i < mutateCount) //decide if the chromosome's genes should be |
| | mutated |
| 12. | P[i][j] = uniqueRandi ( P[i][:], 1, numberOfNodes )//random |
| | genes no duplicates |
| 13. | else |
| 14. | P[i][j] = genePool[ Randi( 1, numberOfSensors ) ] //use parent |
| | genes |
| 15. | endif |
| 16. | endfor |
| 17. | endfor |
| 18. | return P //return new generation |

### Experimental Example 4.3: Evaluation

The two algorithms provide different approaches to solving our optimization problem. The greedy algorithm sacrifices the exploration of the solutions space to provide solutions at a low computational cost. The genetic algorithm performs a deeper exploration of the large search space associated with this problem at the cost of additional computational resources.

The algorithms are capable of generating globally optimal solutions. As the optimization problem does not scale well, determining the globally optimal solutions using an exhaustive search was done on only placing two, three and four sensors on the 229-node test grid. The performance of the greedy algorithm in relation to the globally optimal solutions generated by a brute force approach is shown in Table 5 where sensor node locations are the node IDs in the graph selected as sensor locations. The performance of the genetic algorithm in relation to the same globally optimal solutions is shown in Table 6.

TABLE 5
Initial greedy algorithm results.

| Number | Sensor node | Meters | Sensor node | Meters |
|---|---|---|---|---|
| of | locations | Covered by | location | Covered by |
| Sensors | (Best) | (Best) | (greedy) | (greedy) |
| 2 | 61, 27 | 3816.7 | 61, 27 | 3816.7 |
| 3 | 61, 55, 12 | 6887.8 | 61, 55, 27 | 6871 |
| 4 | 61, 27, 12, 55 | 9008 | 61, 55, 27, 12 | 8908.7 |

The placement of the first two sensors was a globally optimal solution as expected as the initialSensorPair function is an exhaustive search. However, the greedy algorithm did not find the best solution for placing three and four sensors as seen in table 5. It must be noted however, that the difference in the greedy solutions and the globally optimal solutions are less than 1.5%. The greedy algorithm only provides near optimal solutions in these cases. These initial results show that the greedy algorithm may be an effective method for optimizing sensor locations but it may not be able to find globally optimal solutions.

TABLE 6
Initial genetic algorithm results.

| | | | Sensor node | Meters |
|---|---|---|---|---|
| Number | Sensor node | Meters | locations | Covered by |
| of | locations | Covered by | (Genetic | (Genetic |
| Sensors | (Best) | (Best) | Algorithm) | Algorithm) |
| 2 | 61, 27 | 3816.7 | 61, 27 | 3816.7 |
| 3 | 61, 55, 12 | 6887.8 | 61, 55, 12 | 6887.8 |
| 4 | 61, 27, 12, 55 | 9008 | 61, 55, 27, 12 | 9008 |

The results in Table 6 show that the genetic algorithm is able to find the best possible solutions for all three test cases while the greedy algorithm does not. These results show that the genetic algorithm can provide the necessary flexibility needed to find solutions that the greedy algorithm cannot.

The two algorithms provide different approaches to solving our optimization problem. The greedy algorithm sacrifices the exploration of the search space to provide solutions at a low computational cost. The genetic algorithm performs a deeper exploration of the large search space associated with this problem at the cost of additional computational resources. At this point we have established that the genetic algorithm is able to generate the optimal solutions for all three initial tests where the greedy algorithm was unable to do so.

We now perform a deeper evaluation on the two algorithms and provide a comparison between both methods. This main evaluation of the algorithms was done on placing varying amounts of sensors on a test grid provided by [Industry-Partner 2018]. Tests were carried out on this grid by each algorithm for the placement of two sensors up to ten sensors. These tests are performed on placing of two sensors up to ten sensors to first establish which method may be more effective. Additional tests are then performed in section 5.9 to expand the test cases for the selected solution to incorporate practical scenarios of the optimization method. The grid provided by [Industry-Partner 2018] contained 229 nodes. In the grid provided, each node is a random point in the electrical grid that allows the shape of the grid to be represented [Industry-Partner 2018]. Each node can be seen as a waypoint for the cables that make up the grid. The cost of placing the first two sensors is included in the results even though it will always be the globally optimal solution so that a complete comparison can be made between the algorithms.

The solutions generated for these cases by both methods were evaluated against each other. The testing is to establish the effectiveness of the greedy algorithm with a lower computational cost and a restrictive search and compare it with genetic algorithm that provides more flexibility at a higher computational cost. The results of this comparison will determine if the GA is able to generate better solutions by exploring more of the search space or if the greedy algorithm's is able to generate better solutions.

We now look at the resources used by each algorithm to gauge the efficiency of the two methods. We start with the greedy algorithm's time complexity. When placing the first two sensors an exhaustive search of all possibilities is done first. After the initial two sensors are placed the cost of each additional sensor is equivalent to a search of each unused node to determine the next best node. The time complexity is the sum of the cost placing the first two sensors and adding each additional sensor needed giving us O(n!) where n is the number of nodes that can be used as locations for sensors in the grid.

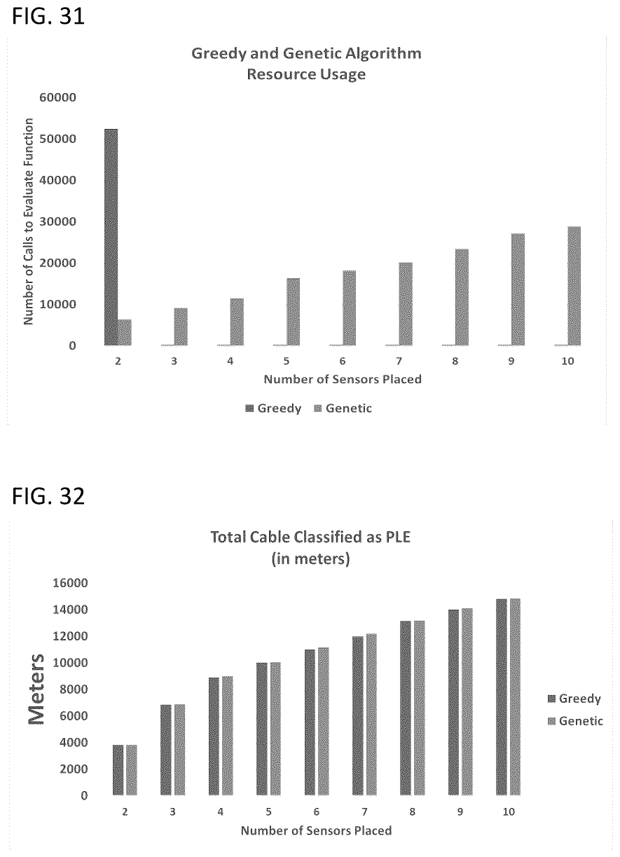

To determine the number of iterations and resources needed by the GA we allow the genetic algorithm to run until the genetic algorithm has fully converged on a solution. However, a time complexity for the genetic algorithm cannot be expressed in terms of the number of nodes as its run time and resources vary with each run and are tied to the convergence of the algorithm. To compare the GA to the greedy algorithm we use the actual resources used by both methods expressed as the number of calls to the evaluation function. The data shown in FIGS. 31, 32, and 34 for the genetic and hybrid algorithm tests are averages taken from fifty tests for each number of sensors placed to account for the variability of the solutions that may be returned by these methods. The greedy algorithm data does not require averages, as it returns the same solutions for each number of sensors placed.

FIG. 31 shows the difference in computational cost (expressed as the number of calls to the evaluate function) between the greedy algorithm and the genetic algorithm for optimizing sensor locations in the 229-node test grid.

The genetic algorithm uses much more resources on average in all cases (as expected) but the initial placement of two sensors. The genetic algorithm only requires 18% of the resources used by the exhaustive search for placing the initial two sensors. The quality of the solutions generated by each method is analyzed to determine how much of an increase in solution performance is attained from the additional computational cost of the genetic algorithm.

FIG. 32 shows the amount of cable covered under primary localization by the greedy algorithm's solutions and the genetic algorithm's solutions for all of the tests performed.

FIG. 32 shows that the coverage gained by both methods is almost identical. This is a strong indicator that the greedy algorithm is more efficient at optimizing the location of sensors. In the initial tests the greedy algorithm did not find the absolute best solution for placing 3 or 4 sensors. However, the greedy algorithm only fell short by 16.8 and 99.3 meters (less than 1%) which may not have much impact when a line worker (someone who is trying to repair the fault) is looking for the fault location. Looking at all of the tests from placing two to ten sensors there is little to separate the two methods in final solution performance as seen in FIG. 32. The genetic algorithm was only able to increase performance by an average of around 0.6% an amount not visible in the data displayed in FIG. 32. However, the genetic algorithm's solutions were consistently better than the greedy algorithm's solutions. The genetic algorithm generated better solutions (though marginally) than the greedy algorithm.

The results of our comparison are now used to establish a hybrid optimization strategy (Algorithm 11) for placing sensors in the grid. The greedy algorithm is more efficient in computational cost than the genetic algorithm for the tests performed. However, the greedy algorithm is not able to generate optimal solutions in some cases as seen in Table 5. The greedy algorithm is limited by which solutions it can consider as each iteration chooses a sensor location that cannot be changed. It is possible that better solutions can be built by allowing a chosen sensor location to be changed.

The greedy algorithm may be used as the core optimization strategy as it has been proven to be very good at generating near optimal solutions with relatively little resources. The genetic algorithm may be used as a secondary optimization process that takes as input the solutions generated by the greedy algorithm. The genetic algorithm would take the less expensive greedy solution and place it in the initial population set of solutions used by the genetic algorithm effectively seeding the genetic algorithm with high performing genes. The genetic algorithm would apply the genetic operators to the population and run as normal. This would now allow the sensor locations in a greedy solution to be modified by mutation and crossover. From a genetic algorithm perspective, this would effectively widen the scope of the solution generation process to the global search space. This facilitates the modification of the greedy solution to potentially increase solution quality.

ALGORITHM 11
Hybrid

| | |
|---|---|
| 1. | Input: numberOfSensors, numberOfNodes, Nodes |
| 2. | Output: locations |
| 3. | greedySolution = Greedy(numberOfSensors) |
| 4. | E = null //2D array to hold elite chromosomes |
| 5. | convergeCounter = 0, max = 50, pSize = 100 |
| 6. | P = initialize( numberOfSensors , pSize, greedySolution ) //create |
| 7. | while convergeCounter < max do //execute until the algorithm has |
| 8. | for i = 1:size(P) do //evaluate each chromosome (solution) |
| 9. | performance(i) = Evaluate( P(i) ) //function as defined in section |
| 10. | Endfor |
| 11. | prevE = E //temporarily store old elite set to check for change |
| 12. | E = update(performance, E, P) //update E with best solutions in |
| 13. | if ( prevE = E ) //check for a change in elite set (detect convergence) |
| 14. | convergeCounter = convergeCounter + 1 |
| 15. | Else |
| 16. | convergeCounter = 0 //reset counter whenever a change is detected |
| 17. | endif |
| 18. | X = select(E, P, numberOfSensors) //choose chromosomes for |
| 19. | P=crossoverAndMutate(X, convergeCounter, numberOfSensors, |
| 20. | Endwhile |
| 21. | return locations = max( E ) //return best solution |

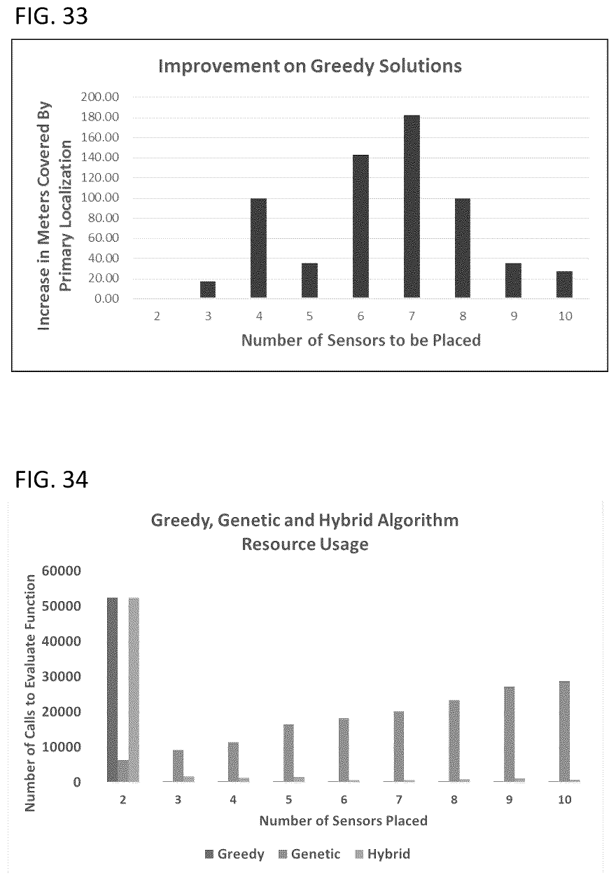

There are two changes made to the original genetic algorithm (Algorithm 6). These two changes are that the greedy algorithm (Algorithm 5) is called in line 3 and the greedy solution generated is then passed to the initialize function (line 6). At line 6 the initialize function generates the initial population but inserts the greedy solution into the set. This allows the greedy solution to be modified so that all sensor locations chosen by the greedy method can be changed. FIG. 33 shows the increase in the meters covered under PLE for the optimization solutions generated by the hybrid approach when compared to the greedy approach.

The hybrid algorithm is able to find better solutions than the greedy algorithm for every case except placing 2 sensors as this is the globally optimal solution. The hybrid algorithm has successfully modified the non-optimal greedy solutions to create the globally optimal solutions for placing 3 and 4 sensors (by comparing the hybrid solutions with the optimal solutions generated in the initial tests seen in Table 5 and Table 6). However, it must be noted that the improvements at best were 180 meters. This equates to a 1.5% increase in performance for the biggest improvement. The hybrid approach allows better solutions to be generated but only marginally so.

FIG. 34 shows the resource usage using the hybrid approach compared to the genetic and greedy algorithm. The hybrid algorithm's resource usage also includes the initial call to the greedy algorithm to generate the initial solution placed in the genetic algorithm's initial population. For placing the initial 2 sensors the genetic algorithm is the most effective, generating the globally optimal solution using less than 20% of the resources of the other methods. When placing the first 2 sensors the genetic algorithm could therefore be used. For the remaining problem sizes, the hybrid method can generate better solutions than the greedy method while using less resources than the genetic method. The hybrid method is successful in providing a more reliable method than the greedy approach as it is not limited by the iterative process while being more efficient than the genetic algorithm.

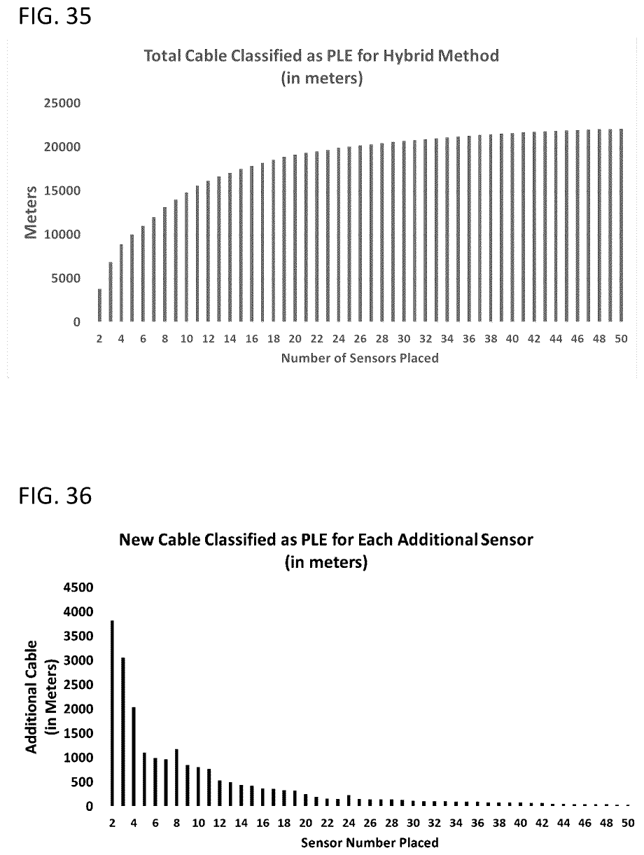

The hybrid method provides a reliable and efficient way of calculating the best locations to place n sensors in an electrical grid to maximize PLE coverage. The primary consideration for the application of such a method is choosing the number sensors (choosing n) that should be placed in the electrical grid for any given scenario. Additional tests were performed using the hybrid method for placing up to fifty sensors on the test grid. The tests were done to provide a more complete view of the coverage that could be attained for a larger number of sensors which may provide insight into selecting a value for n (the number of sensors) in a given scenario. The PLE coverage for these tests is shown in FIG. 35.

FIG. 36 shows the amount of PLE coverage gained for each additional sensor. This coverage per sensor metric provides a useful perspective of the optimization results. FIG. 36 shows that there is a significant drop in additional coverage as more sensors are added. The total cable in the test grid is 23 kilometers. The amount of coverage for adding the first 5 sensors is 43% (over 10 kilometers). However, the next 5 sensors (10 total) only provide 20% more coverage. After placing another 5 sensors (15 total) the increase in PLE coverage has fallen to 1%. The coverage added per sensor consistently declines as more sensors are added. The question formed from these results is at what point is it no longer beneficial from a cost-based perspective. This is a particularly interesting perspective and is a strong indicator that there is no single value for n (the number of sensors to place in the grid) that would work in all cases. This is because each implementation of the fault localization solution may require n (the number of sensors to place in the grid) to be calculated based on the needs and standards of the company using the solution.

The test data analysis indicates that the selection of n is not a simple process if optimization is desired and requires specific information and decision making from the user employing the fault localization solution. The hybrid optimization algorithm does however provide a means for assisting the process of selecting the number of sensors to place in the grid.
The hybrid optimization algorithm can be used to generate a coverage per sensor metric that can be used with a threshold (of meters) so that once adding an nti sensor does not add enough PLE coverage then no more sensors are placed.
Similarly to the first point, the coverage per sensor metric can also be used to establish a cost per meter of coverage for each sensor using the cost of a sensor and the PLE coverage gained for each sensor. This can also be used in conjunction with some threshold to ensure the cost per meter coverage does not exceed a certain amount.
The optimization algorithm can also be used to provide a business with an estimate of the coverage for a particular number of sensors that may be set based on a budget. If a budget is provided, the total PLE coverage for that budget can be calculated by running the optimization algorithm using the number of sensors the budget can support as the value for n.
It is also possible that the number of sensors can be determined by the desired coverage under the PLE. Let us say for example that the electric company wants 80% of the grid to be covered under the primary localization scheme. In this scenario the value of n is increased until the desired percentage is covered under the primary localization scheme. By doing this an adequate number of sensors (value for n) and the locations where this coverage can be achieved can be calculated.

These examples for the application of the optimization algorithm is not an exhaustive list. More ways of determining n can be derived from any number of characteristics present in the business model of a company employing the optimization algorithm.

The greedy approach in most cases is as good as the genetic algorithm while using significantly less resources. The greedy approach would have been the chosen method but for the fact that the greedy algorithm cannot handle all cases due to the incremental nature of its approach. The greedy algorithm was unable to handle cases where a better solution may be found by changing the sensor locations of previous iterations. To address this issue a hybrid approach was developed that used the greedy approach to generate the initial solution and then applied the genetic algorithm to allow the solution to be further modified. The hybrid approach was then able to provide a much more efficient optimization strategy. We acknowledge that in environments where resources are very limited, the greedy algorithm can act as an effective optimization strategy for the optimization problem. For cases where there is not such a strict resource constraint the hybrid approach can be used to ensure solution quality.

A limitation of this experimental example is created because the optimization algorithm takes a set of nodes and edges that represent the electrical grid and selects sensor locations from that set of nodes. Traditionally, the nodes of the graphical representation of a grid are the busses of that electrical grid. A bus refers to a location where the grid branches off into different directions. The optimization algorithm in this case would be choosing a set of busses on which the sensors would be placed. This was seen a restricted approach to determining sensor locations as sensors in practice can be placed anywhere on the power cables. We acknowledge that sensors could be placed in locations other than busses. The set of nodes for the grid provided by our industry partner for our tests represented the busses and other (random) locations along the cables between those busses. This grid was therefore able to allow our optimization algorithm to consider locations between busses as possible locations which aligns with our goal of acknowledging sensor locations may be non-bus locations. The work presented in this chapter shows that the algorithm can optimize the locations of sensors not only at busses but also when the possible locations are anywhere in the electrical grid. An extension of this experimental example is an optimization algorithm that does not need nodes to be provided and/or can incorporate the edges of a graph into the optimization process.

Another modification of an optimization strategy is to use of historical data for prioritized monitoring. Access to historical data on the age of components (like transformers etc.) and the locations of previous faults, would allow high risk areas of the grid to be identified. These high-risk areas could be prioritized for monitoring by adjusting the weight of the edge in the graph that corresponds to that high-risk area. The use of a suitable metric would be established, and would be added to the weight of the edge. This could allow the optimization algorithm to prioritize these edges resulting in an increased effort to cover the high-risk areas under the primary localization scheme.

### Reference List for Experimental Example 4

Bandyopadhyay, S. and S. Saha. Some Single- and Multiobjective Optimization Techniques. Unsupervised Classification, Springer Berlin Heidelberg: 17-58, (2013).
Barron, A. R., A. Cohen, W. Dahmen and R. A. DeVore. “Approximation and learning by greedy algorithms.” The annals of statistics 36(1): 64-94, (2008).
Cormen, T. H., C. E. Leiserson, R. L. Rivest and C. Stein. Introduction to algorithms, MIT press, (2009).
Crossley, P. A. and P. G. McLaren. “Distance Protection Based on Travelling Waves.” IEEE Transactions on Power Apparatus and Systems PAS-102(9): 2971-2983, (1983).
Das, S., S. Kulkarni, N. Karnik and S. Santoso. Distribution fault location using short-circuit fault current profile approach. 2011 IEEE Power and Energy Society General Meeting, (2011).
Dereventsov, A. V. “Comparison of the convergence rate of pure greedy and orthogonal greedy algorithms.” Mathematical Notes 92(3): 485-489, (2012).
DeVore, R. A. and V. N. Temlyakov. “Some remarks on greedy algorithms.” Advances in Computational Mathematics 5(1): 173-187, (1996).
Hamo, Y. and S. Markovitch. The COMPSET Algorithm for Subset Selection. IJCAI, (2005).
Hizam, H. and P. A. Crossley. Single Ended Fault Location Technique On a Radial Distribution Network Using Fault Generated Current Signals, (2006).
Hunte, J., H. Lutfiyya and A. Haque. Fault Localization in Smart Grids Using Segmentation. ICC 2021—IEEE International Conference on Communications, (2021).
Industry-Partner. Ontario Electricity Provider, (2018).
Karnik, N., S. Das, S. Kulkarni and S. Santoso. Effect of load current on fault location estimates of impedance-based methods. 2011 IEEE Power and Energy Society General Meeting, (2011).
Lin, S., Y. Rong, X. Sun and Z. Xu. “Learning Capability of Relaxed Greedy Algorithms.” IEEE Transactions on Neural Networks and Learning Systems 24(10): 1598-1608, (2013).
Magnago, F. H. and A. Abur. “Fault location using wavelets.” IEEE Transactions on Power Delivery 13(4): 1475-1480, (1998).
Qian, C., J.-C. Shi, Y. Yu and K. Tang. On Subset Selection with General Cost Constraints. IJCAI, (2017).
Saha, M., F. Provoost and E. Rosolowski. “Fault location method for MV cable network.” (2001).
Sapountzoglou, N., B. Raison and N. Silva. Fault Detection and Localization in LV Smart Grids. 2019 IEEE Milan PowerTech, (2019).
Škumát, T. and E. Ž. Open Phase Fault Localization in a Medium Voltage Distribution Grid Using Smart Meters. 2019 20th International Scientific Conference on Electric Power Engineering (EPE), (2019).
Srinivas, M. and L. M. Patnaik. “Adaptive probabilities of crossover and mutation in genetic algorithms.” IEEE Transactions on Systems, Man, and Cybernetics 24(4): 656-667, (1994).
Srinivas, M. and L. M. Patnaik. “Genetic algorithms: a survey.” Computer 27(6): 17-26, (1994).
Takagi, T., Y. Yamakoshi, M. Yamaura, R. Kondow and T. Matsushima. “Development of a New Type Fault Locator Using the One-Terminal Voltage and Current Data.” IEEE Transactions on Power Apparatus and Systems PAS-101(8): 2892-2898, (1982).
Temlyakov. “Nonlinear Methods of Approximation.” Foundations of Computational Mathematics 3(1): 33-107, (2003).
Trindade, F. C. L. and W. Freitas. “Low Voltage Zones to Support Fault Location in Distribution Systems With Smart Meters.” IEEE Transactions on Smart Grid 8(6): 2765-2774, (2017).
Trindade, F. C. L., W. Freitas and J. C. M. Vieira. “Fault Location in Distribution Systems Based on Smart Feeder Meters.” IEEE Transactions on Power Delivery 29(1): 251-260, (2014).
Vafaie, H. and I. F. Imam. Feature selection methods: genetic algorithms vs. greedy-like search. Proceedings of the international conference on fuzzy and intelligent control systems, (1994).

An illustrative version and several variants of electrical grid fault localization systems and methods have been described above without any intended loss of generality. Further examples of modifications and variation are now provided. Still further variants, modifications and combinations thereof are contemplated and will be apparent to the person of skill in the art. It is to be understood that illustrative variants or modifications are provided for the purpose of enhancing the understanding of the person of skill in the art and are not intended as limiting statements.

For example, the system and method is not limited to fault localization in distribution grids, and can readily accommodate fault localization in any portion of an electrical grid, including a transmission grid.

As another example, the system and method can accommodate variation in measurement devices detecting a fault event and are not limited to current sensors. Any convenient sensor or meter or other measurement device that is able to reliably detect a fault event at a location remote from the fault location may be incorporated in the system and method.

As another example, various processing techniques for identifying fault event data may be accommodated by the system and method, and any suitable algorithm or machine learning implementation can be used to analyze measured fault event data to determine timing of a fault event and if needed timing of an associated automated circuit opening or circuit closing event.

As another example, sensors, meters or other measurement devices need not be incorporated with a microcomputer and other configurations of analysis of fault detection data are contemplated.

As another example, the system and method can accommodate variation from graph theory representation of an electrical grid, and any geographical marker scheme that can segment the electrical grid to a desired spatial resolution and maintain fidelity of geographic coordinates may be implemented.

As another example, geographic coordinates are not limited to GPS, and other available geographic coordinate schemes are contemplated. Geographical markers can be any mathematical or spatial coordinate framework to measure and label locations in geographic space of the electrical grid. Spatial reference system (SRS) or coordinate reference system (CRS) are examples of such frameworks used to precisely measure locations on the surface of the Earth as coordinates and have a long history of development for example in geoinformatics, cartography, geographic information systems, surveying, remote sensing, and civil engineering. This has led to their standardization in international specifications such as the EPSG codes and ISO 19111:2007 Geographic information-Spatial referencing by coordinates, prepared by ISO/TC 211, also published by the Open Geospatial Consortium as Abstract Specification, Topic 2: Spatial referencing by coordinate. Many spatial reference system standards include: Geographic coordinate system (or geodetic)—a spherical coordinate system measuring locations directly on the Earth using latitude and longitude; Geocentric coordinate system (or Earth-centered Earth fixed)—a three-dimensional cartesian coordinate system that models the Earth as a three-dimensional object, measuring locations from a center point, usually the center of mass of the Earth, along x, y, and z axes aligned with the equator and the prime meridian; Projected coordinate system (or planar, grid)—a cartesian coordinate system that models the Earth (or more commonly, a large region thereof) as a plane, measuring locations from an arbitrary origin point along x and y axes more or less aligned with the cardinal directions; Engineering coordinate system (or local, custom)—a cartesian coordinate system (2-D or 3-D) that is created bespoke for a small area, often a single engineering project, over which the curvature of the Earth can be safely approximated as flat without significant distortion. Publicly recognized examples of spatial reference systems include Universal Transverse Mercator coordinate system, British national grid reference system, Chinese Global Navigation Grid Code, Hellenic Geodetic Reference System 1987, Irish grid reference system, Irish Transverse Mercator, Israeli Transverse Mercator, Israeli Cassini Soldner, Jordan Transverse Mercator, Lambert conformal conic projection, International mapcode system, Military Grid Reference System, United States National Grid.

Alternatives to latitude-longitude spatial referencing is an area of active development. For example, geohash.org is a geocoding system encodes locations as strings of letters and digits; what3words is a geolocation proprietary algorithm that uniquely transforms the location of every 3×3 m square on Earth into three pronounceable words; Open Location Codes (also called plus codes) invented by Google is a fully open code with reference implementations in many languages, a public-facing website, and extensive documentation; Mapcodes is a geocoding system that features very short codes for densely populated places.

Geographical markers as incorporated in a map or graph representation of an electrical grid can be as numerous and as granular as desired. For example, in a graph representation, edges can have geographical markers at any desired interval supported by a coordinate system and nodes are a subset of the geographical markers that can be used to characterize a totality of edges in a system. Geographical markers designating a grid component, such as an edge, may be subdivided into any number of plurality of geographical markers depending on the precision of the coordinate system. A geographic marker designating an edge may be one or more of a plurality of geographic markers located within the edge; for example a geographic marker in the center of an edge may be used as a designating reference and be associated with a plurality of subordinate geographic markers that sequentially extend at desired intervals from a first end of the edge to a second end of the edge. Thus, a geographic marker designating an edge may be a selection of convenience, and the selected geographic marker may be associated with first, second, third or any greater number of associated geographical markers that occur at desired intervals in the edge.

As another example, the system and method are not limited to a specific type of electrical grid and may be adapted to any type of electrical grid in any country in the world.

As another example, benefit of the system and method are not limited to measurement devices that exhibit clock drift, and the system and method are readily applicable to measurement devices that maintain synchronized clocks. The system and method provide benefits other than reconciling unsynchronized clocks including for example, accurate fault localization, flexible sensor placement configurations, cost effective sensor placement configuration, optimized sensor placement configuration, or mitigation of recloser variability and operational time variability.

As another example, the recloser wave signal may be used to synchronize the data separately from the localization of the fault. The steps to synchronize the travelling wave fault data across multiple sensors are:
Step 1—Use the known distances between the sensors and the recloser to calculate the expected delays between the recloser signal arrival time at each sensor.
Step 2—Calculate the delay between the fault and recloser signals for each sensor.
Step 3—Use the expected delays of the recloser signals between sensors (calculated in step 1) to correctly align the recloser signals and align the fault signals relative to their corresponding recloser signals (using the delays calculated in step 2).

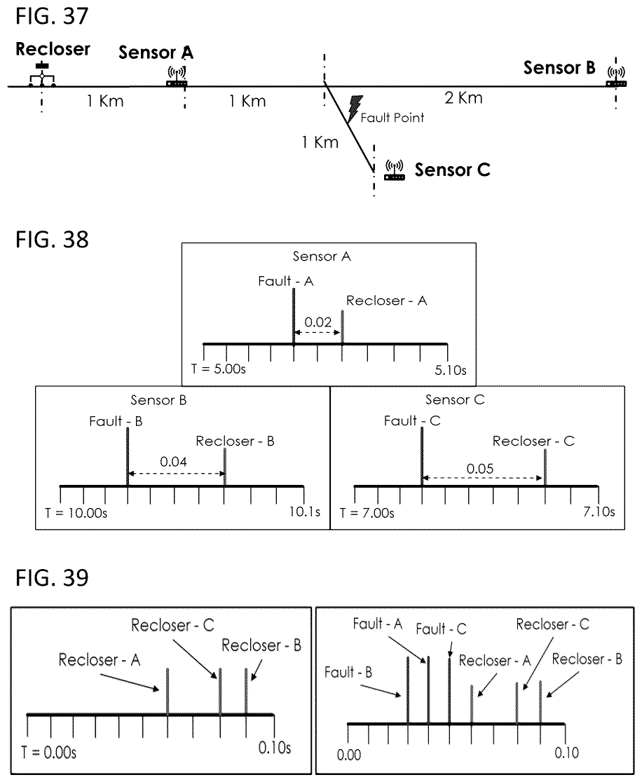

FIG. 37 shows an example of a grid with a recloser, three sensors and a fault occurring at the fault point on the grid. Table 7 shows the corresponding adjacency matrix of FIG. 37 for the sensors and recloser.

TABLE 7
Adjacency matrix of sensors and reclosers.

| | Recloser | Sensor A | Sensor B | Sensor C |
|---|---|---|---|---|
| | (Km) | (Km) | (Km) | (Km) |
| Recloser (Km) | 0 | 1 | 4 | 3 |
| Sensor A (Km) | 1 | 0 | 3 | 2 |
| Sensor B (Km) | 4 | 3 | 0 | 3 |
| Sensor C (Km) | 3 | 2 | 3 | 0 |

The first step outlined above is completed using a propagation delay of 0.01 s per Km, the delays of the recloser signal between each sensor is calculated and shown in Table 8.

TABLE 8
Delays between recloser signal times of each sensor.
Recloser Delay

| A - B | A - C | B - C |
|---|---|---|
| −0.03 | −0.02 | 0.01 |

The second step, calculating the delays between the fault and recloser signal is shown in FIG. 38. The delays for sensor A, B and C are 0.02, 0.04 and 0.05 respectively as shown in Table 9.

TABLE 9
Delays between recloser and fault signals for each sensor.
Recloser - Fault Delay

| A | B | C |
|---|---|---|
| 0.02 | 0.04 | 0.05 |

The values in Table 9 are generated by simulating the example shown in FIG. 37 and recording the recloser and fault signals at each sensor. Using Sensor A as an example, say the fault occurs at T=0. Sensor A will get the fault signal at T=0.015. That fault signal will reach the recloser at T=0.025. The recloser signal would then leave the recloser and arrive at sensor A at T=0.035. Using Equation 8 from Experimental Example 2 the Recloser—Fault Delay for Sensor A would be calculated as shown below.

$$d e l a {y}_{f}^{R} ( A ) = {T}_{A}^{R} - {T}_{A}^{f} = 0.035 - 0.015 = 0.02$$

The final step is to place the recloser signals the appropriate distance apart using the recloser delays between each sensor from Table 8. The fault signal for each sensor can then be inserted at the recorded distance from the recloser signals for each sensor using the Reclosure-Fault delays from Table 9. FIG. 39 shows the final synchronized fault and recloser signals.

Using Equation 5 from Experimental Example 2 the fault location can be determined by using sensor A and sensor C's data and is shown below.

$$abs ( \frac{{delay}_{C}^{A} - ( ( {delay}_{f}^{R ,} ( C ) - {delay}_{A , C}^{R} ) - {delay}_{f}^{R} ( A ) )}{2} ) / s$$

$$abs ( \frac{0.02 - ( 0.05 - ( - 0.02 ) ) - 0.02 )}{2} ) / s = abs ( \frac{- 0.03}{2} ) / 0.01 = 1.5 Km$$

The final calculation is that the fault is 1.5 Km away from sensor A. Accordingly, the synchronization of multiple devices can occur separately from the calculation of the fault location. This is an example of how all sensors in a grid can be synchronized. Then using Equation 5 defined in Experimental Example 2, the fault is localized which only requires the use of two sensors on either side of the fault. Even though many sensors may be placed in a distribution grid, only two sensors are needed to determine a fault's location using Equation 5; the only requirement in choosing the two sensors is that the sensors must be on either side of the fault (the fault must be between the two sensors chosen).

As another example, the system and method are not limited to reclosers and may be adapted to any other switching device (also referred to as switchgear) that can automatically open or close a circuit or can automatically control power flow of a circuit. A primary function of switchgear is protection, which is interruption of short-circuit and overload fault currents while maintaining service to unaffected circuits. Switchgear also provides isolation of circuits from power supplies. In a closed configuration switchgear conducts flow of electricity, and while in an open configuration switchgear interrupts the flow of electricity. When triggered by a fault event switchgear opens a circuit and generates a circuit opening wave signal and upon returning to a closed circuit generates a circuit closing wave signal. Therefore, the switchgear is the initiating/originating source or location of the circuit opening wave signal and the circuit closing wave signal. Both the circuit opening and circuit closing wave signals are encompassed by the term switchgear-controlled wave signal, as the switchgear controls the occurrence of circuit opening and circuit closing wave signals. Switchgear is used to de-energize equipment to allow work to be done or to clear faults and examples of switchgear include reclosers, electrical disconnect switches, fuses or circuit breakers. Since switchgear encompass reclosers and circuit breakers and the like, the term switchgear-controlled wave signal can encompass terms such as recloser wave signal or recloser signal and circuit breaker wave signal or circuit breaker signal and the like.

As another example, the system and method are not limited by operational variability of a recloser or other automated switching device as variation in operational times such as variation in trip delays may be mitigated as treatment of measured time data to calculate time delays between a plurality of measurement devices can reduce or remove impact of switching device variability and variability in operational times.

Also, an important benefit of the disclosed localization method, and more specifically Equation 5, is accommodation of variability in operational times such that the varying operational times of different reclosers or different switchgear are not a barrier to a successful implementation. Equation 5 accounts for the variability in recloser operation times. To show this, recall FIG. 37 and its discussion pertaining to Equation 5. In the example of FIG. 37, the recloser opens (and emits a travelling wave) immediately upon detecting the fault signal. If there were a delay in the recloser operation, this delay would be present in both the delay_{f}^{R}′(C) and delay_{f}^{R}(A) components of the equation (as these record the recloser arrival time at each sensor). The recloser delay in these two components would cancel each other out as they are ultimately subtracted from each other. For example, say there is a delay of 0.02 seconds for the recloser operation (i.e the recloser takes 0.02 s to open when the fault signal is detected). The equation would still generate the same answer of 1.5 Km as shown below.

$$abs ( \frac{{delay}_{C}^{A} - ( ( {delay}_{f}^{R ,} ( C ) - {delay}_{A , C}^{R} ) - {delay}_{f}^{R} ( A ) )}{2} ) / s \vert ¶$$

$$abs ( \frac{0.02 - ( ( 0.07 - ( - 0.02 ) ) - 0.04 )}{2} ) / s = abs ( \frac{- 0.03}{2} ) / 0.01 = 1.5 Km ¶$$

The additional 0.02 s would be seen in the delay_{f}^{R}′(C) and delay_{f}^{R}(A) components as highlighted (values 0.07 and 0.04 shown in bold font) but the net result would still be the same:
−0.03.

We can therefore see that different recloser operating times would not have any effect on localizing the fault and this localization method would therefore work with any recloser.

It is also possible to place a sensor at the recloser itself and record the delay between when the fault signal is detected reaching the recloser and the time the recloser signal is detected leaving the recloser and subtract that delay 0.02 s from the delay_{f}^{R}′(C) and delay_{f}^{R}(A) components which would also provide a correct localization result.

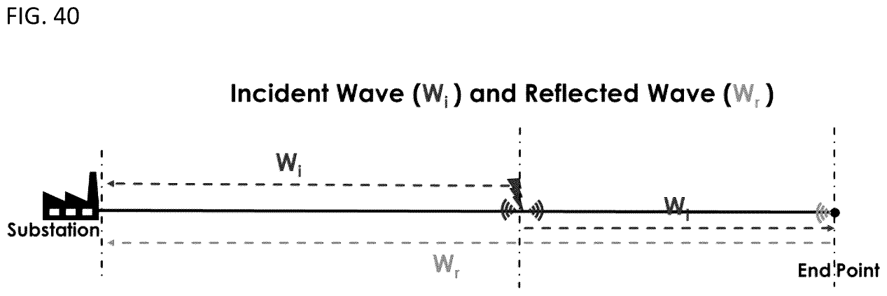

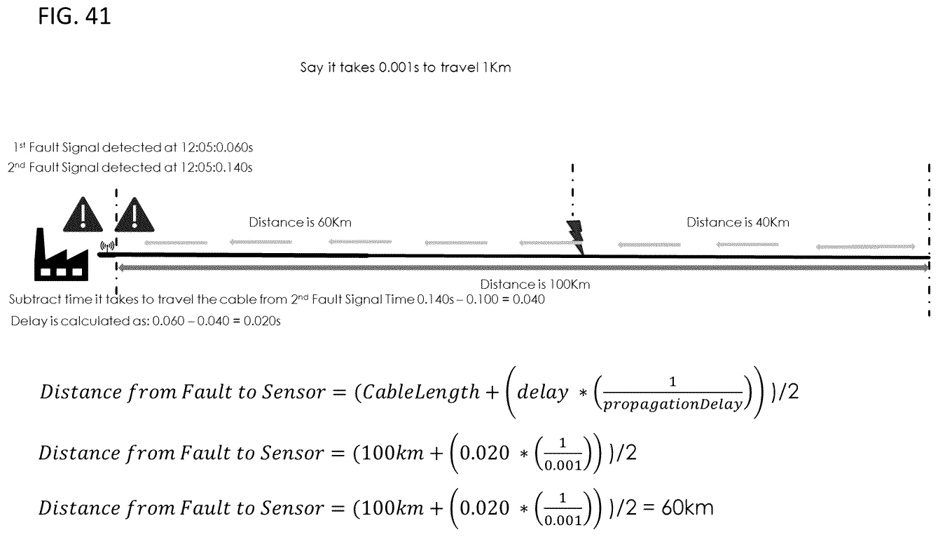

As another example, the system and method can accommodate alternatives to synchronization of sensors and pairwise comparisons of sensors. While recloser wave signal (also referred to recloser signal) has been used to synchronize the fault signal times across all sensors in the grid to then create a fault key, the recloser signal can also be used to generate the fault key without explicitly synchronizing fault signals detected by sensors. To understand this alternative, consider that when a fault occurs in the grid a wave is emitted from the fault location and travels across the grid like a ripple in a pond. This incident wave reflects off the end of the line and travels back up the line. FIG. 40 shows this phenomenon on a single line. FIG. 41 shows how this has been traditionally used in transmission grids with a single sensor for fault localization where:
delay is the difference in the fault signal arrival time at the sensor and the endpoint not the fault and reflected signal arrival times at the sensor).
CableLength is the length of the cable between the sensor and the endpoint.

This approach has not previously been used in distribution grids because the origin of the reflected wave (the path of the reflected wave) must be known, which is not possible in distribution grids due to the large number of end points. Travelling wave methods used in the transmission grid generates a distance from a sensor (S₁ in FIG. 27) using the incident and reflected wave to determine the fault location. Since a transmission grid has one power line there is only one source for the reflected wave which is at the endpoint representing the end of the power line. In distribution grids (as shown in FIG. 27) however, there are many endpoints (referred to as EP₁, EP₂ and EP₃ in FIG. 27). The reflected waves detected can come from any of these endpoints. As a result, a single endpoint and reflected wave cannot be established. The source endpoint of the reflected wave used to localize a fault must be known. If the sources of the reflected waves cannot be determined as is the case in the distribution grid, then only a list of possible locations will be generated. With this in mind, an alternate method of generating the fault key that does not rely on explicit synchronization of sensors is now described.

The recloser signal can be used as a known endpoint/source of the reflected wave for all sensors in the grid. The recloser receives a fault signal and then opens its switch, which emits a signal that then travels across the grid (referred to as recloser signal or recloser wave signal). This process is the same as if a fault signal reflects off an endpoint in the grid. Effectively a fault signal hits the recloser and a recloser signal is then emitted across the grid analogous to a fault signal bouncing off an endpoint and generating a reflected wave.

The advantage of the recloser signal is that it has a unique profile, so it would not match the fault signal or the usual reflected waves traversing the grid. As the recloser location (now effectively an endpoint) is known, it can be used in a similar equation shown in FIG. 41 to calculate a fault distance/time from a sensor independently of any other sensor. A single sensor can perform this calculation by itself, removing the need for fault event alignment (synchronization) across multiple sensors and removing a requirement for pairwise comparisons.

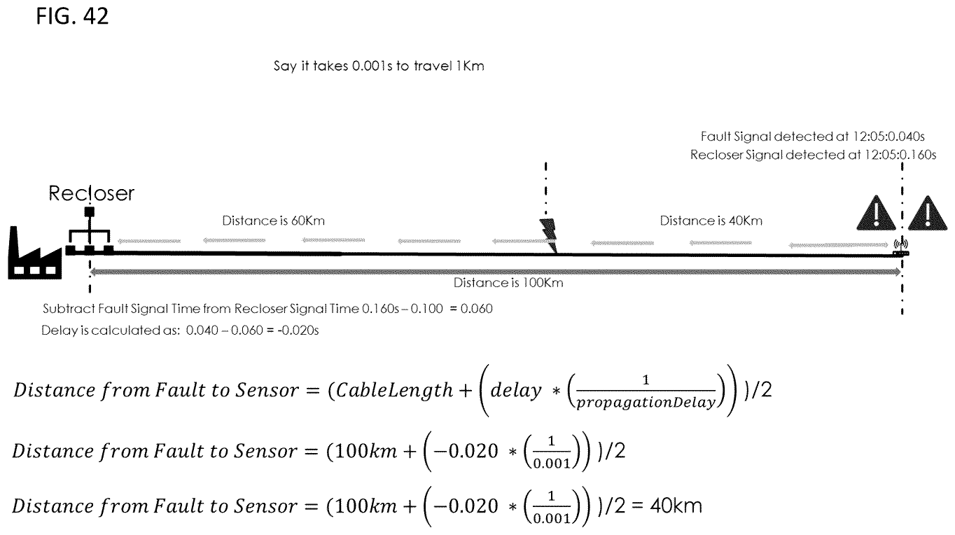

Referring to FIG. 42, the sensor would be placed at the end of the cable downstream of the area that is to be monitored. The recloser would be upstream near the substation. The same equation in FIG. 41 is used in FIG. 41 where:
delay would become the delay in the fault signal arrival times at the sensor and the recloser
CableLength would become the distance between the sensor and the recloser.

Once the fault time/distance is determined by each sensor, they can be used to generate the fault key. The fault distance for each sensor can be converted back into times and then optionally subtracted from each other according to the sensor pairings to generate the fault key as described in the experimental examples. Then the fault can then be localized using the localization method described in the experimental examples. This alternate approach is further improved by recording or measuring the delay between the recloser receiving the fault signal and emitting the recloser signal. The typical reflected wave does not have a delay as the fault signal is immediately reflected. The recloser signal would have a delay based on how long it takes for the recloser to open the switch after receiving the fault signal. For this improvement, a sensor can be placed at the recloser to record the arrival of the fault signal and the departure of the recloser signal. This delay would then be subtracted from delay in the equation shown in FIG. 42 (the delay between the fault signal arriving at the sensor and recloser). This alternate approach reconfirms that a recloser wave signal is an important consideration for fault localization in distribution grids as it solves the issues of multiple reflected waves and their locations etc. This alternate recloser usage described here also provides for a single sensor localization, albeit with a predictable reduced accuracy compared to the localization method demonstrated in the experimental examples.

This single sensor localization provides an alternative localization approach that does not require the pairwise subtraction of sensor data shown in the experimental examples. It is possible to utilize the fault localization solution without a pairwise calculation of edge keys or the pairwise calculation of a fault key (as shown in the experimental examples both edge key and fault key calculations involve subtracting times for all pairs of sensors within a group or a plurality of sensors). Fault localization without pairwise calculations for edge or fault keys is possible by using the recloser as an endpoint and its signal as a reflected wave. Leveraging the recloser in this manner allows the data captured by a single sensor to generate a fault location with respect to that sensor's location. The fault location could be calculated as a distance from the sensor, or if convenient the fault location could be calculated as a signal propagation time from the fault location to the sensor.

The edge keys could be simplified from being a pairwise subtraction of signal delays between sensors, to being the distance/signal propagation time from each end of an edge (node) to each sensor, establishing a time window (upper and lower bound) for that edge to propagate a wave signal to each sensor independently. The distance to the fault calculated by a sensor can then be used/compared to the edge's time window for that one sensor to determine if the fault may have occurred on that edge or at that node. Due to branching, the distance of a fault from a sensor may result in multiple edge or node matches for the fault. Additional sensors can then be used to determine a single fault location. When a single sensor's distance to fault results in multiple geographical locations, additional distance to fault calculations from other sensors can be used to determine the actual fault location. The geographical locations of other sensors can be compared to find overlaps in the generated fault locations of each sensor. Any locations that do not overlap with all other sensors can be removed from consideration for the fault location. This would allow a final fault location to be determined from multiple sets of possible fault locations (each set generated by one sensor) by eliminating possible locations that are not supported by the other sensors.

With respect to the edge keys, each sensor's fault distance calculation can be used to match against the edge key for that sensor (where the edge key is generated as distance/signal propagation time from the edge to each sensor rather than the delay in travelling wave arrival times for pairs of sensors). The edge that overlaps for all sensor fault distance locations would be the actual fault location (once adequate sensors are included in the process). With this approach a pair wise subtraction for the edge keys or the fault key becomes an option that provides improvement, but that is not critical for operability.

As another example, the system and method can accommodate variation in computer technology stack or infrastructure including variation in server configurations, communication protocols, memory structures and memory formats. As another example, embodiments disclosed herein, or portions thereof, can be implemented by any suitable programming of one or more computer systems or devices with computer-executable instructions embodied in a non-transitory computer-readable medium. When executed by a processor, these instructions operate to cause these computer systems and devices to perform one or more functions particular to embodiments disclosed herein. Programming techniques, computer languages, devices, and computer-readable media necessary to accomplish this are known in the art.

In an example, a non-transitory computer readable medium embodying a computer program for electrical grid fault localization may comprise: computer program code for storing a representation of the electrical grid as a plurality of geographical markers; computer program code for storing a plurality of sets of expected time data, each one of the plurality of sets of expected time data associated with each one of the plurality of geographical markers, each member of the set of expected time data based on an expected signal propagation time from at least one of the plurality of geographical markers to at least one of a plurality of current sensors; computer program code for identifying a fault event wave signal with the plurality of current sensors coupled to the electrical grid; computer program code for receiving measured time data of the fault event from the plurality of current sensors to generate a set of fault event time data; and computer program code for matching the set of fault event time data to at least one of the plurality of sets of expected time data and identifying/outputting at least one matched geographical marker. In another related example, the computer readable medium further comprises computer program code for calculating the set of fault event time data based on determining a time delay between the fault event wave signal and a switchgear-controlled wave signal at each current sensor. In still another related example, the computer readable medium further comprises computer program code for determining placement of the plurality of current sensors with a current-sensor-placement component based on maximizing unique sets within the plurality of sets of expected time data.

The computer readable medium is a data storage device that can store data, which can thereafter, be read by a computer system. Examples of a computer readable medium include read-only memory, random-access memory, CD-ROMs, magnetic tape, optical data storage devices and the like. The computer readable medium may be geographically localized or may be distributed over a network coupled computer system so that the computer readable code is stored and executed in a distributed fashion.

Computer-implementation of the system or method typically comprises a memory, an interface and a processor. The types and arrangements of memory, interface and processor may be varied according to implementations. For example, the interface may include a software interface that communicates with an end-user computing device through an Internet connection. The interface may also include a physical electronic device configured to receive requests or queries from a device sending digital and/or analog information. In other examples, the interface can include a physical electronic device configured to receive signals and/or data relating to a fault event wave signal or a switchgear-controlled wave signal, for example from a current sensor device or other measurement device or a switchgear device.

Any suitable processor type may be used depending on a specific implementation, including for example, a microprocessor, a programmable logic controller or a field programmable logic array. Moreover, any conventional computer architecture may be used for computer-implementation of the system or method including for example a memory, a mass storage device, a processor (CPU), a graphical processing unit (GPU), a Read-Only Memory (ROM), and a Random-Access Memory (RAM) generally connected to a system bus of data-processing apparatus. Memory can be implemented as a ROM, RAM, a combination thereof, or simply a general memory unit. Software modules in the form of routines and/or subroutines for carrying out features of the system or method can be stored within memory and then retrieved and processed via processor to perform a particular task or function. Similarly, one or more method steps may be encoded as a program component, stored as executable instructions within memory and then retrieved and processed via a processor. A user input device, such as a keyboard, mouse, or another pointing device, can be connected to PCI (Peripheral Component Interconnect) bus. If desired, the software may provide an environment that represents programs, files, options, and so forth by means of graphically displayed icons, menus, and dialog boxes on a computer monitor screen. For example, any number of graph images or mapped representations of an electrical grid or any parameters calculated from current sensor data may be displayed, including for example a waveform of a recorded fault event wave signal or a fault localization marked on a map or graph representation of the electrical grid or a pattern/configuration of current sensor placement marked on a map or graph representation of the electrical grid.

Computer-implementation of the system or method may accommodate any type of end-user computing device including computing devices communicating over a networked connection. The computing device may display graphical interface elements for performing the various functions of the system or method, including for example display of a fault localization or an optimized current sensor placement configuration. For example, the computing device may be a server, desktop, laptop, notebook, tablet, personal digital assistant (PDA), PDA phone or smartphone, and the like. The computing device may be implemented using any appropriate combination of hardware and/or software configured for wired and/or wireless communication. Communication can occur over a network, for example, where remote control of the system is desired.

If a networked connection is desired the system or method may accommodate any type of network. The network may be a single network or a combination of multiple networks. For example, the network may include the internet and/or one or more intranets, landline networks, wireless networks, and/or other appropriate types of communication networks. In another example, the network may comprise a wireless telecommunications network (e.g., cellular phone network) adapted to communicate with other communication networks, such as the Internet. For example, the network may comprise a computer network that makes use of a TCP/IP protocol (including protocols based on TCP/IP protocol, such as HTTP, HTTPS or FTP).

In view of the examples and variants disclosed herein, most implementations of the system and method will include a plurality of current sensors coupled to an electrical grid; a representation of the electrical grid as a plurality of geographical markers; a plurality of sets of expected time data, each one of the plurality of sets of expected time data associated with each one of the plurality of geographical markers, each member of the set of expected time data based on an expected signal propagation time from at least one of the plurality of geographical markers to at least one of the plurality of current sensors; measuring time data of a fault event with the plurality of current sensors; generating a set of fault event time data; and matching the set of fault event time data to at least one of the plurality of sets of expected time data.

Each of the plurality of current sensor may be operably connected to a microcomputer and a wireless communication device—other device configurations are also feasible. Each of the plurality of current sensors is configured to measure and record a disruption in normal current flow and is therefore configured to identify a fault event wave signal. In an example, the fault event wave signal is identified for each current sensor by threshold value monitoring. In another example, the fault event wave signal is identified for each current sensor by wave form pattern recognition monitoring. The number and placement configuration of current sensors can be determined algorithmically to obtain a desired accuracy of fault localization, for example by implementing a current-sensor-placement component as described in Experimental Example 4 for determining placement of the plurality of current sensors. In an example, the current-sensor-placement component determines placement of the plurality of current sensors based on maximizing unique sets within the plurality of sets of expected time data. In another example, the current-sensor-placement component generates a plurality of placement configurations for a requested and predetermined number of the plurality of current sensors and selects at least one of the plurality of placement configurations that maximizes unique sets within the plurality of sets of expected time data. In yet another example, the current-sensor-placement component generates a plurality of placement configurations for a requested and predetermined amount of unique sets within the plurality of sets of expected time data and selects at least one of the plurality of placement configurations that provides a minimum number of the plurality of current sensors and each respective location of the minimum number of the plurality of current sensors to achieve the requested amount of unique sets. An amount of unique sets can be expressed as an absolute amount or as a percentage or ratio compared to total number of sets, or any other convenient mathematical expression.

Geographical markers may be derived from any spatial or coordinate referencing system or geocoding system of which many examples are available, each geographical marker identifying a unique and unambiguous location of the electrical grid. Thus, the geographical marker by definition provides a unique identifier that can be mapped in geographical space; nevertheless each geographical marker may be designated with further unique identifiers as may be desired for convenience of data structuring and computing. The density of geographical markers will be at least 1 geographical marker per branch of the electrical grid. Typically, the density will be at least two geographical markers per branch of electrical grid, and in many instances may be higher. Consider that most geographical marker systems are able to achieve a resolution of less than 5 meter intervals between adjacent geographical markers, and some can achieve a resolution of less than 1 meter intervals. In an example, of a branch of the electrical grid having a 1 kilometer cable length, representation of the branch by 1000 geographical markers consistently spaced at 1 meter intervals is feasible, and in this example one or more of the 1000 geographical markers may be selected for generating a set of expected time data based on expected signal propagation time from the selected geographical markers to each of the plurality of current sensors. In an extension of this example, each member of the set of expected time data can be calculated based on a differential of the expected signal propagation time from the selected geographical marker to each unique pair combination of sensors among the plurality of current sensors. Keeping with the example of 1000 geographical markers representing a 1 kilometer branch, the term a geographical marker, meaning one or more geographical markers, may reference the full group of 1000 geographical markers, and selected geographical markers for the purpose of generating sets of expected time data may be referenced as a first subordinate marker, a second subordinate marker, a third subordinate marker and the like, or a first spatial point, a second spatial point, a third spatial point, and the like. In an example of selecting two geographical markers (or first and second subordinate markers or first and second spatial points) at either end of a selected segment of the branch, the set of expected time data can comprise a plurality of pairs of associated first and second members, the first member based on a first expected signal propagation time from a first spatial point of each geographical marker, the second member based on a second expected signal propagation time from a second spatial point of each geographical marker, the first and second members providing lower and upper bounds of signal propagation time from each geographical marker, where the term geographical marker represents the group of geographic markers extending along the selected segment.

The number of members of the set of expected time data will typically be determined by the number of current sensors, since each member of the set is based on an expected signal propagation time from the selected geographical marker to each of the current sensors. For example, the value k calculated in Equation 1 presented in Experimental Example 1 provides the number of members in the set per selected geographical marker for a pairwise subtraction of all unique pair combinations of current sensors.

The fault event time data can be calculated based on the fault event wave signal measured and recorded by each of the plurality of current sensors. Additionally, generation of fault event time data is benefitted by calculation based on a fault event wave signal and a switchgear wave signal. Generation of fault event time data is further benefitted by calculation based on determining a time delay between the fault event wave signal and the switchgear wave signal at each current sensor. In a further example, the set of fault event time data is calculated based on determining a time delay between the fault event wave signal and the switchgear wave signal at each current sensor and based on determining an expected signal propagation time from an originating switchgear location of the switchgear-controlled wave signal to each current sensor. In a still further example, the set of fault event time data is calculated based on determining a time delay between the fault event wave signal and the switchgear-controlled wave signal at each current sensor and adding the determined time delay to a corresponding expected signal propagation time from an originating switchgear location of the switchgear-controlled wave signal to each current sensor.

The fault event time data is a set of measured data that matches the set of expected time data as it pertain to number of set members—ie., the set of expected time data will typically have the same number of members for each geographical marker and collected plurality of the sets of expected time data will each have either the same number or an integer multiple (often 2×) of the number of members in the fault event time data. For example, the experimental examples show the set of expected time data pertaining to two selected geographical markers (first and second spatial points) of an edge to generate upper and lower bounds of expected time data for each edge, and therefore the number of members of the set of expected time data is twice (2×) the number of members in the fault event time data. Deviations from matching numbers of set members can be accommodated in implementations where a disadvantage of reduced accuracy is accepted. Also, the fault event time data is a set of measured data that matches the set of expected time data as it pertains to pairwise calculation of current sensor data or single sensor data without any pairwise calculation. In an example where the set of expected time data as is generated by pairwise current sensor calculation, each member of the set of fault event time data is calculated based on a differential of the fault event wave signal propagation time from the fault location to a pair of the plurality of current sensors, and the pairs in the set of fault event time data is ordered in the same sequence as the pairs in the set of expected time data. In another example where the set of expected time data as is generated by pairwise current sensor calculation, subsequent to identifying a matched geographical marker by querying the collected plurality of sets of expected time data and comparing with the set of fault event time data, fault localization relative to the at least one matched geographical marker is calculated based on selecting a pair of current sensors; and determining a time interval between a differential of expected signal propagation time from the matched geographical marker to the selected pair of current sensors and a differential of the fault event wave signal propagation time from the fault location to the selected pair of current sensors; and converting the time interval to a distance interval related to the at least one matched geographical marker.

The switchgear, such as recloser or circuit breaker, controls the timing and waveform shape/pattern of switchgear wave signal by switchgear control mechanisms that function to determine timing of opening or closing a circuit upon identifying a fault event disruption of the normal current flow. Since the switchgear mechanism controls timing and shape/pattern of a wave signal generated as a result of opening a circuit or closing a circuit, the terms switchgear wave signal and switchgear-initiated wave signal and switchgear-controlled wave signal may be used interchangeably.

Embodiments described herein are intended for illustrative purposes without any intended loss of generality. Still further variants, modifications and combinations thereof are contemplated and will be recognized by the person of skill in the art. Accordingly, the foregoing detailed description is not intended to limit scope, applicability, or configuration of claimed subject matter.

1. An electrical grid fault localization system comprising:
a plurality of current sensors coupled to the electrical grid;
a memory for storing a representation of the electrical grid as a plurality of geographical markers, and for storing a plurality of sets of expected time data, each one of the plurality of sets of expected time data associated with each one of the plurality of geographical markers, each member of the set of expected time data based on an expected signal propagation time from at least one of the plurality of geographical markers to at least one of the plurality of current sensors;
a processor communicative with the plurality of current sensors and the memory, the processor configured to receive measured time data of a fault event from the plurality of sensors to generate a set of fault event time data and to match the set of fault event time data to at least one of the plurality of sets of expected time data and identifying at least one matched geographical marker.

2. The system of claim 1, wherein each member of each set of expected time data is calculated based on a differential of the expected signal propagation time from one of the plurality of geographical markers to a pair of the plurality of current sensors.

3. The system of claim 1, wherein each set of expected time data comprises a plurality of pairs of associated first and second members, the first member based on a first expected signal propagation time from a first spatial point of each geographical marker, the second member based on a second expected signal propagation time from a second spatial point of each geographical marker, the first and second members providing lower and upper bounds of signal propagation time from each geographical marker.

4. (canceled)

5. The system of claim 2, wherein the set of fault event time data is calculated based on determining a time delay between the fault event wave signal and a switchgear wave signal at each current sensor.

6-11. (canceled)

12. The system of claim 5, wherein fault localization relative to the at least one matched geographical marker is calculated based on selecting a pair of current sensors; and determining a time interval between a differential of expected signal propagation time from the matched geographical marker to the selected pair of current sensors and a differential of the fault event wave signal propagation time from the fault location to the selected pair of current sensors; and converting the time interval to a distance interval related to the at least one matched geographical marker.

13-15. (canceled)

16. The system of claim 1, further comprising a current-sensor-placement component for determining placement of the plurality of current sensors.

17. (canceled)

18. The system of claim 16, wherein the current-sensor-placement component generates a plurality of placement configurations for a requested and predetermined number of the plurality of current sensors and selects at least one of the plurality of placement configurations that maximizes unique sets within the plurality of sets of expected time data.

19-28. (canceled)

29. An electrical grid fault localization method comprising:
storing a representation of the electrical grid as a plurality of geographical markers;
storing a plurality of sets of expected time data, each one of the plurality of sets of expected time data associated with each one of the plurality of geographical markers, each member of the set of expected time data based on an expected signal propagation time from at least one of the plurality of geographical markers to at least one of a plurality of current sensors;
identifying a fault event wave signal with the plurality of current sensors coupled to the electrical grid;
receiving measured time data of the fault event from the plurality of current sensors to generate a set of fault event time data; and
matching the set of fault event time data to at least one of the plurality of sets of expected time data and identifying at least one matched geographical marker.

30. The method of claim 29, wherein each member of each set of expected time data is calculated based on a differential of the expected signal propagation time from one of the plurality of geographical markers to a pair of the plurality of current sensors.

31. The method of claim 29, wherein each set of expected time data comprises a plurality of pairs of associated first and second members, the first member based on a first expected signal propagation time from a first spatial point of each geographical marker, the second member based on a second expected signal propagation time from a second spatial point of each geographical marker, the first and second members providing lower and upper bounds of the expected signal propagation time from each geographical marker to at least one current sensor.

32. (canceled)

33. The method of claim 30, wherein the set of fault event time data is calculated based on determining a time delay between the fault event wave signal and a switchgear wave signal at each current sensor.

34-39. (canceled)

40. The method of claim 33, wherein fault localization relative to the at least one matched geographical marker is calculated based on selecting a pair of current sensors; and determining a time interval between a differential of expected signal propagation time from the matched geographical marker to the selected pair of current sensors and a differential of the fault event wave signal propagation time from the fault location to the selected pair of current sensors; and converting the time interval to a distance interval related to the at least one matched geographical marker.

41-43. (canceled)

44. The method of claim 29, further comprising determining placement of the plurality of current sensors with a current-sensor-placement component.

45. (canceled)

46. The method of claim 44, wherein determining placement of the plurality of current sensors is based on generating a plurality of placement configurations for a requested and predetermined number of the plurality of current sensors and selecting at least one of the plurality of placement configurations that maximizes unique sets within the plurality of sets of expected time data.

47-56. (canceled)

57. A non-transitory computer readable medium embodying a computer program for electrical grid fault localization comprising:
computer program code for storing a representation of the electrical grid as a plurality of geographical markers;
computer program code for storing a plurality of sets of expected time data, each one of the plurality of sets of expected time data associated with each one of the plurality of geographical markers, each member of the set of expected time data based on an expected signal propagation time from at least one of the plurality of geographical markers to at least one of a plurality of current sensors;
computer program code for identifying a fault event wave signal with the plurality of current sensors (measurement devices) coupled to the electrical grid;
computer program code for receiving measured time data of the fault event from the plurality of current sensors to generate a set of fault event time data; and
computer program code for matching the set of fault event time data to at least one of the plurality of sets of expected time data and identifying/outputting at least one matched geographical marker.

58. The computer readable medium of claim 57, wherein each member of each set of expected time data is calculated based on a differential of the expected signal propagation time from one of the plurality of geographical markers to a pair of the plurality of current sensors.

59. The computer readable medium of claim 57, wherein each set of expected time data comprises a plurality of pairs of associated first and second members, the first member based on a first expected signal propagation time from a first spatial point of each geographical marker, the second member based on a second expected signal propagation time from a second spatial point of each geographical marker, the first and second members providing lower and upper bounds of the expected signal propagation time from each geographical marker to at least one current sensor.

60. The computer readable medium of claim 58, wherein the set of fault event time data is calculated based on determining a time delay between the fault event wave signal and a switchgear wave signal at each current sensor.

61. The computer readable medium of claim 60, wherein fault localization relative to the at least one matched geographical marker is calculated based on selecting a pair of current sensors; and determining a time interval between a differential of expected signal propagation time from the matched geographical marker to the selected pair of current sensors and a differential of the fault event wave signal propagation time from the fault location to the selected pair of current sensors; and converting the time interval to a distance interval related to the at least one matched geographical marker.

62. The computer readable medium of claim 57, further comprising computer program code determining placement of the plurality of current sensors with a current-sensor-placement component.

63. The computer readable medium of claim 62, wherein determining placement of the plurality of current sensors is based on generating a plurality of placement configurations for a requested and predetermined number of the plurality of current sensors and selecting at least one of the plurality of placement configurations that maximizes unique sets within the plurality of sets of expected time data.
